(19) United States
(12) Patent Application Publication
(10) Pub. No.: US 2026/0279619 A1
(43) Pub. Date: Sep. 17, 2026

(54) High Temperature Superconductors

(71) Applicant: Quantum Designed Materials Ltd., Rehovot (IL)

(72) Inventors: Refael Gatt, Maxkeret Batya (IL); Gili Yaniv, Rehovot (IL); Peter Rusian, Rehovot (IL)

(21) Appl. No.: 18/875,700

(22) PCT Filed: Jun. 20, 2023
(86) PCT No.: PCT/US2023/025792

§ 371 Date: Dec. 16, 2024

Related U.S. Application Data
(60) Provisional application No. 63/353,487, filed on Jun. 17, 2022.
(60) Provisional application No. 63/445,237, filed on Feb. 13, 2023.

(51) Int. Cl. H01B 12/02

(52) U.S. Cl. CPC H01B 12/02

(57) ABSTRACT

This disclosure relates to compounds of formula (I): LₙDₘ(BₓB′₁₋ₓ)ᵣ(ZₜZ′₁₋ₜ)_{q}MₚA_{y}A′ₛ (I), in which n, m, x, r, t, q, p, y, s, L, D, B, B′, Z, Z′, M, A, and A′ are defined in the specification. These compounds can exhibit superconductivity at a high temperature. This disclosure also features a fault current limiter device, including an electrically conducting element including a superconducting material having a superconducting state below a critical current and a normal conductive state above the critical current.

### CROSS-REFERENCE TO RELATED APPLICATIONS

The present application claims priority to U.S. Provisional Application Ser. No. 63/445,237, filed on Feb. 13, 2023 and U.S. Provisional Application Ser. No. 63/353,487, filed on Jun. 17, 2022, the contents of which are hereby incorporated by reference in their entirety.

### TECHNICAL FIELD

This disclosure relates to high temperature superconductors, as well as related methods and devices.

### BACKGROUND

In 1986, Bednorz and Muller surprised the solid state physics community with their announcement of a new class of superconducting materials having critical temperatures (Tc) significantly higher than those achieved previously [Bednorz, et al., Z. Phys. B 64, 189 (1986)]. These materials are ceramics consisting of copper oxide layers separated by buffer cations. In Bednorz and Muller's original compound (LBCO), the buffer cations are lanthanum and barium. Inspired by their work and motivated by his own critical temperature under pressure measurements, Paul Chu synthesized a similar material in which the buffer ions were yttrium and barium. This material was YBCO, the first superconductor with a Tc above the boiling point of liquid nitrogen (77K) [Wu, et al., Phys. Rev. Lett. 58, 908 (1987)]. The highest critical temperature reported to date is 164K, obtained by a mercury based superconductor at a pressure of 31 GPa. [Putilin, et al., Nature 362, 226 (1993), and Chu, et al., Nature 365, 323 (1993)].

### SUMMARY

This disclosure is based on the unexpected discovery that certain metal oxides containing alkali metal ions in their crystal structures are superconductors at extremely high temperatures (e.g., up to about 550K).

In one aspect, this disclosure features a compound of formula (I):

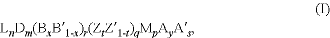

in which n is a number from 0 to 3; m is a number from 0 to 6, x is a number from 0.1 to 1; r is a number from 1 to 8; t is a number from 0 to 1; q is a number from 0 to 6; p is a number from 1 to 7; s is a number from 0 to 20; y is a number from 0 to 20; L includes at least one metal ion selected from the group consisting of transition metal ions and post-transition metal ions; D includes at least one element selected from the group consisting of the elements in Groups IIIA and IVA in the Periodic Table; B includes at least one first alkali metal ion; B′ includes at least one first ion selected from the group consisting of alkaline earth metal ions and rare earth metal ions; Z includes at least one second alkali metal ion; Z′ includes at least one second ion selected from the group consisting of alkaline earth metal ions and rare earth metal ions; M includes at least one transition metal ion; A includes at least one anion; and A′ includes at least one halogen anion. The compound of formula (I) is a crystalline compound.

In another aspect, this disclosure features a compound, which is a crystalline metal oxide containing at least one transition metal ion (e.g., Cu ion), at least one alkaline earth metal ion (e.g., Sr or Ca) or at least one rare earth metal ion, and at least one chalcogen anion, in which from 10% to 100% of the at least one alkaline earth metal ion or at least one rare earth metal ion is replaced by an alkali metal ion and from 10% to 100% of the at least one chalcogen anion is replaced by a halogen anion.

In another aspect, this disclosure features a method that includes (1) mixing a crystalline metal oxide with an alkali metal halogen salt containing an alkali metal cation and a halogen anion to form a mixture, in which the metal oxide contain at least one transition metal ion and at least one alkaline earth metal ion and the atomic ratio between the alkali metal ion and the at least one alkaline earth metal ion is higher than 1:1; and (2) sintering the mixture at an elevated temperature to form a crystalline compound containing the alkali metal cation and the halogen anion.

In another aspect, this disclosure features a method that includes (1) mixing a metal oxide (e.g., CuO and Bi₂O₃) with an alkali metal halogen salt containing an alkali metal cation and a halogen anion to form a mixture, in which the metal oxide contain at least one transition metal ion and the atomic ratio between the alkali metal ion and the at least one alkaline earth metal ion is higher than 1:1; and (2) sintering the mixture at an elevated temperature to form a crystalline compound containing the alkali metal cation and the halogen anion.

In another aspect, this disclosure features a device that includes a superconducting compound described herein and is superconductive (e.g., exhibiting superconductive properties such as capable of carrying a superconductive current) at a temperature of at least 200K (e.g., at least 273K).

In yet another aspect, this disclosure features a composition containing the superconducting compound described herein.

In a further aspect, the disclosure features a fault current limiter device, including an electrically conducting element including a superconducting material having a superconducting state below a critical current and a normal conductive state above the critical current, the superconducting material including a crystalline compound including at least one alkali metal ion, at least one first ion selected from the group consisting of alkaline earth metal ions and rare earth metal ions, and at least one halogen ion; and a pair of electrical contacts arranged at opposite ends of the electrically conducting element, the pair of electrical contacts configured to connect the electrically conducting element to an electrical circuit; and a heat sink in thermal communication with the superconducting material of the electrically conducting element.

Other features, objects, and advantages will be apparent from the description, drawings, and claims.

### DESCRIPTION OF DRAWINGS

FIG. 1 is a scheme illustrating an octahedral cluster in the crystal structure of a superconducting compound described herein.

FIG. 2A is a scheme illustrating the relationship among the energy band of a material, its Fermi level and its corresponding conductance according to the Wilson rule and the present disclosure.

FIG. 2B presents the Fermi landscape of a simple metal and a superconductor. Left panel: a simple isotropic 2D metal. The Fermi surface appears as a 1D circle. Right panel: The Fermi landscape of an isotropic 2D superconductor according to the present disclosure. The Fermi volume appears as a 2D ring.

FIG. 2C presents realistic anisotropic Fermi landscape. Left panel: a scheme illustrating measured Fermi landscape of Bi2212 [Norman et. al., Phys. Rev. B, 52, 615 (1995)]. Center panel: a scheme illustrating the Fermi landscape of a possible higher temperature superconductor predicted by the inventor. Right panel: a scheme illustrating the Fermi landscape of a possible even higher temperature superconductor predicted by the inventor.

FIGS. 3A, 3B, and 3C show known electronic structure results measured by ARPES.

FIG. 4A shows known cluster calculations. The energy difference 2δ is displayed as function of the distance between the buffer ion and the plane. a) The effect of the buffer ion radius on 2δ. b) The effect of the buffer ion charge on 2δ. c) The effect of the buffer ion softness on 2δ.

FIG. 4B presents a table listing the properties of known cuprate superconductors. The critical temperature can be explained by the model described herein. The crystal structure of LBCO and YBCO are given for clarity.

FIG. 5 is a scheme illustrating another exemplary crystal structure of a superconducting compound described herein.

FIG. 6 is a schematic illustration of an example power transmission network and fault current limited.

FIG. 7 is a schematic illustration and an example fault current limiter (FCL) device including a superconducting material.

FIG. 8A is a perspective view of an example resistive FCL element.

FIG. 8B is a plan view of the resistive FCL element shown in FIG. 8A.

FIG. 8C is a sectional view through the section A of the resistive FCL element shown in FIG. 8B.

FIG. 9A is a current-voltage plot illustrating the threshold current transition between a superconducting and a normal conducting state of a FCL.

FIG. 9B is a current-voltage plot illustrating the threshold for a FCL at four different temperatures.

FIG. 10 is a schematic diagram of an example inductive FCL device.

FIG. 11A is a perspective view of an example inductive FCL element.

FIG. 11B is a plan view of the example inductive FCL element shown in FIG. 11A.

FIG. 11C is a sectional view through the section A of the inductive FCL element shown in FIG. 11B.

FIG. 12 is a schematic diagram of an example FCL device with a cooling subsystem.

FIG. 13 is a schematic showing an example of a micro pulling down crystal growth apparatus.

FIGS. 14A-14B are photographs showing examples of crystal fibers.

FIG. 15A is a micrograph showing an example of a sintered compound.

FIG. 15B is a micrograph showing an example of a compound obtained by a micro pulling down crystal growth process.

FIGS. 16-17 are charts showing examples of magnetic responses of superconducting compounds as a function of temperature.

FIG. 18 is a plot showing magnetic moment as a function of temperature for Compound 1.

FIG. 19 is a plot showing resistance as a function of current for Bi2212 at 20° C. and ambient pressure.

FIG. 20 is a plot showing resistance as a function of current for Compound 1 at 20° C. and ambient pressure.

FIG. 21 is a plot showing magnetic moment hysteresis for a temperature ramp for Compound 1.

FIG. 22 is a plot showing resistance as a function of current for Compound 2 at 20° C. and ambient pressure.

FIG. 23A is a plot showing voltage as a function of current for a first sample of Compound 2 at 20° C. and ambient pressure.

FIG. 23B is a plot showing voltage as a function of current for a second sample of Compound 2 at 20° C. and ambient pressure.

FIG. 23C is a plot showing voltage as a function of current for a third sample of Compound 2 at 20° C. and ambient pressure.

FIG. 24A is a plot showing resistance as a function of current for another sample of Compound 2 at 75° C. and ambient pressure.

FIG. 24B is an XRD spectrum of Compound 2.

FIG. 25 is a plot showing magnetic moment hysteresis for a temperature ramp for Compound 4.

FIG. 26 is a plot showing magnetic moment hysteresis for a temperature ramp for Compound 5.

Like reference symbols in the various drawings indicate like elements.

### DETAILED DESCRIPTION

This disclosure generally relates to high temperature superconductors (HTS), i.e., compounds exhibiting superconductivity at a high temperature (e.g., from 273K to 550K), to methods of their preparation, and to their use.

In some embodiments, a high temperature superconductor described herein is a compound of formula (I).

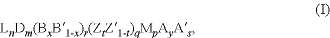

in which n is any number from 0 to 3 (e.g., 0, 1, 2, or 3); m is any number from 0 to 6; x is any number from 0.1 to 1; r is any number from 1 to 8 (e.g., 1, 2, 3, 4, 5, 6, 7, or 8); t is any number from 0 to 1; q is any number from 0 to 6 (e.g., 0, 1, 2, 3, 4, 5, or 6); p is any number from 1 to 7 (e.g., 1, 2, 3, 4, 5, 6, or 7); s is any number from 0 to 20; y is any number from 0 to 20; L includes at least one metal ion selected from the group consisting of transition metal ions and post-transition metal ions; D includes at least one element selected from the group consisting of the elements in Groups IIIA (e.g., B, Al, Ga, In, or Tl) and IVA (e.g., C, Si, Ge, Sn, or Pb) in the Periodic Table; B includes at least one first alkali metal ion; B′ includes at least one first ion selected from the group consisting of alkaline earth metal ions and rare earth metal ions; Z includes at least one second alkali metal ion; Z′ includes at least one second ion selected from the group consisting of alkaline earth metal ions and rare earth metal ions; M includes at least one transition metal ion; A includes at least one chalcogen anion; and A′ includes at least one halogen anion. The compound of formula (I) is a crystalline compound. In some embodiments, the compound of formula (I) is a single phase compound. In some embodiments, the compound of formula (I) is a single crystal compound.

In general, n, m, x, r, t, q, p, s, and y can be either an integer or a non-integer.

In some embodiments, the first alkali metal ion is different from the second alkali metal ion. In some embodiments, the first alkali metal ion is the same as the second alkali metal ion. In some embodiments, the first ion assigned to B′ is different from the second ion assigned to Z′. In some embodiments, the first ion assigned to B′ is the same as the second ion assigned to Z′.

In some embodiments, the element assigned to D is different from the metal ion assigned to L. In some embodiment, the element assigned to D is the same as the metal ion assigned to L.

The term “alkali metal ion”, as used herein, refers to an ion containing an element selected from group IA of the periodic table, i.e., Li, Na, K, Rb, Cs, and Fr or any combination thereof. In general, the alkali metal ion can have a valence number of +1. In some embodiments, the alkali metal ion can form a molecular cluster having effective electric charge of between +1 and zero. In such embodiments, the molecular cluster can include one or more negative ions in the proximity of an alkali metal ion such that the positive charge on the alkali metal ion is compensated by the negative charge on the negative ion.

The term “alkaline earth metal ion”, as used herein, refers to a metal ion having a valence number of +2 and containing an element selected from group IIA of the periodic table, i.e., Be, Mg, Ca, Sr, Ba, Ra or any combination thereof.

The term “transition metal ion”, as used herein, refers to a metal ion containing an element selected from Groups IIIB, IVB, VB, VIB, VIIB, VIIIB, IB and IIB of the Periodic Table. In some embodiments, the transition metal mentioned herein can be Sc, Ti, V, Cr, Mn, Fe, Ni, Cu, Zn, Y, Zr, Nb, Tc, Ru, Mo, Rh, W, Au, Pt, Pd, Ag, Mn, Co, Cd, Hf, Ta, Re, Os, Ir, Hg, or any combination thereof. In some embodiments, the transition metal is Cu. In other embodiments, the transition metal is Fe or Zn.

The term “post-transition metal ion”, as used herein, refers to a metal ion containing an element selected from Group IIIA, IVA and VA of the Periodic Table. In some embodiments, the post-transition metal mentioned herein can be Al, Ga, In, Tl, Sn, Pb, Bi, Hg or any combination thereof.

The term “rare earth metal ion”, as used herein, refers to a metal ion containing an element selected from scandium (Sc), yttrium (Y), the lanthanide series of metals (having atomic numbers from 57-71) and the actinide series of metals (having atomic numbers from 89-103) in the Periodic Table. Examples of the rare earth metals in the lanthanide series include La, Ce, Pr, Sm, Gd, Eu, Tb, Dy, Er, Tm, Nd, Yb, or any combination thereof. Examples of the rare earth metals in the actinide series include Ac, Th, Pa, U, Np, Pu, Am, Cm, Bk, Cf, Es, Fm, Md, No, Lr, or any combination thereof.

The term “anion”, as used herein, can include a simple anion, a halide or halogen anion, a chalcogen anion, an organic anion, an oxoanion, a pnictide anion, or any combination thereof. Examples of simple anions include those containing O, S, Se, Te, N, P, As, or Sb as a single atom. Examples of halide or halogen anions include those containing F, Cl, Br, I, At or any combination thereof (such as IBr⁻³, Cl₂I⁻³, Br₂I⁻³ and I₂Cl⁻³). As used herein, the terms “halide anions” and “halogen anions” are used interchangeably. Examples of chalcogen anions include those containing O, S, Se, Te or any combination thereof. Examples of organic anions include acetate (CH₃COO⁻), formate (HCOO⁻), oxalate (C₂O₄⁻²), cyanide (CN⁻) or any combination thereof. Examples of oxoanion include AsO₄⁻³, AsO₃⁻³, CO₃⁻², HCO₃⁻, OH⁻, NO₃⁻, NO₂⁻, PO₄⁻³, HPO₄⁻², SO₄⁻², HSO₄⁻, S₂O₃⁻², SO₃⁻², ClO₄⁻, ClO₃⁻, ClO₂⁻, OCl⁻, IO₃⁻, BrO₃⁻, OBr⁻, CrO₄⁻², Cr₂O₇⁻² or any combination thereof. Examples of pnictide anions include those containing N, P, As, Sb, or any combination thereof. In some embodiments, the anion mentioned herein can be an anion containing any combination of F, Cl, Br, I, O, S, Se, Te, N, P, As, and Sb. In some embodiments, the anion mentioned herein can be NCS⁻, CN⁻, or NCO⁻.

In some embodiments, L in formula (I) can include Bi, Tl, Cu, or Hg.

In some embodiments, D in formula (I) can include C, Si, Ge, Sn, Pb, or Al.

In some embodiments, B in formula (I) can include Li, Na, K, Rb, or Cs.

In some embodiments, B′ in formula (I) can include La, Mg, Ca, Sr, or Ba.

In some embodiments, Z in formula (I) can include Li, Na, K, Rb, or Cs.

In some embodiments, Z′ in formula (I) can include Ca or Y.

In some embodiments, M in formula (I) can include Cu or Fe.

In some embodiments, A in formula (I) can include O, S, Se, P, or As.

In some embodiments, A′ in formula (I) can include F, Cl, Br, or I.

In some embodiments, the compounds of formula (I) can satisfy the following equation: x*r+t*q=s.

In some embodiments, the compound presented herein can include crystal structures of multiple compounds of formula (I). In that case, the compound is called a superstructure or an intergrowth.

In some embodiments, the superconducting compounds of formula (I) can be compounds of formula (Ia):

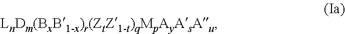

in which n, m, x, r, t, p, q, y, s, L, D, B, B′, Z, Z′, M, A, and A′ are defined above, A″ can include a halogen anion (e.g., F, Cl, Br, or I), and u can be a number from 0 to 20. In such embodiments, p can be any number from 1 to 3. In general, A″ can be the same as or can be different from A′.

In some embodiments, the compounds of formula (Ia) can satisfy the following equation: x*r=s. In such embodiments, the compounds of formula (Ia) can also satisfy the following equation: t*q=u.

In some embodiments, the superconducting compounds of formula (Ia) can be compounds of formula (II):

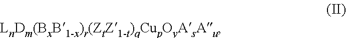

in which n, m, x, r, t, p, q, y, s, u, L, D, B, B′, Z, Z′, A′, and A″ are defined above. In such embodiments, p can be any number from 1 to 3.

In some embodiments, the superconducting compounds of formula (Ia) can be compounds of formula (III):

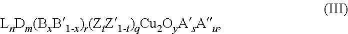

in which n, m, x, r, t, q, y, s, u, L, D, B, B′, Z, Z′, A′, and A″ are defined above. In such embodiments, q can be any number from 1 to 2 and r can be any number from 2 to 4.

Referring to formula (II), a subset of superconducting compounds are those in which q is 0 or 1 and r is any number between 2 and 6. In such embodiments, L can include Bi, Ti, Cu, Pb, or Hg; n can be between 0 and 4; D can be carbon; m can be any number from 0 to 4; B can include K, Rb, or Cs; B′ can include Sr, Ba, Ca and Y; x can be a number from 0.1 to 1; and p can be 1, 2, or 3.

Referring to formula (III), a subset of superconducting compounds are those in which q is 1 and r is 2. In such embodiments, L can include Bi, Ti, Cu, Pb, or Hg; n can be 0, 1, or 2; D can be carbon; m can be any number from 0 to 4; B can include K, Rb, or Cs; B′ can include Sr; x can be a number from 0.1 to 1; t can be 0; and Z′ can include Ca.

Referring to formula (III), another subset of superconducting compounds are those in which q is 1, r is 2, and t is a number greater than 0. In such embodiments, L can include Bi, Tl, or Hg; n can be 0, 1, or 2; D can be carbon; m can be any number from 0 to 4; B can include K, Rb, or Cs; B′ can include Sr; x can be a number from 0.1 to 1; and Z′ can include Ca.

Referring to formula (II), a subset of superconducting compounds are those in which n is 2, m is a number from 0 to 4, r is a number from 2 to 8, q is a number from 0 to 3, p is 4, L is Bi, B is K, Rb, or Cs, B's is Sr, Z is K, Rb, or Cs, and Z′ is Ca.

Referring to formula (II), a subset of superconducting compounds are those in which n is 0, mis a number from 0 to 4, x is 1, t is 1, r is 4, q is 2, p is 4 or 7, B is K, Rb, or Cs, Z is Na.

Referring to formula (II), another subset of superconducting compounds are those in which n is 1, m is a number from 0 to 4, x is 1, t is 0 or 1, r is 2, 4, or 6, q is 0, 1, or 2, p is 1, 2, or 3, L is Hg, B is K, Rb, or Cs, Z is Na, and Z′ is Ba.

Referring to formula (II), another subset of superconducting compounds are those in which n is 1, 2, or 3, mis a number from 0 to 4, x is 1, t is 0 or 1, r is 2, 4, or 6, q is 0, 1, 2, 3, or 4, p is 1, 2, 3, 4, or 5, L is Ti, B is K, Rb, or Cs, Z is Na, and Z′ is Ba.

Referring to formula (II), another subset of superconducting compounds are those in which n is 2, m is a number from 0 to 4, x is 1, t is 1, r is 2, 4, or 6, q is 0 or 2, p is 1 or 3, L is Bi, B is K, and Z is Na.

Referring to formula (II), another subset of superconducting compounds are those in which n is a number from 0 to 1, m is a number from 0 to 1, x is a number from 0.1 to 1, r is 2 or 4, t is a number from 0 to 1, q is 0, 1, or 2, p is 2, 3, or 6, L is Y, B is K, Rb, or Cs, B′ is Sr or Ba, Z is Na, K, Rb, or Cs, and Z′ is Y.

Referring to formula (II), another subset of superconducting compounds are those in which n is 0 or 1, m is a number from 0 to 1, x is a number from 0 to 1, r is 2 or 4, t is a number from 0 to 1, q is 1, p is 2, 3, 4, 5, or 6, L is Cu, B is K, Rb, or Cs, B′ is Ba, and Z is Na.

In some embodiments, the superconducting compounds of formula (I) can be compounds of formula (IV): BMAA′ (IV), in which B, M, A, and A′ are defined above. Examples of such compound include NaCuOF, NaCuOCl, KCuOF, KCuOCl, RbCuOF, RuCuOCl, CsCuOF, and CsCuOCl.

In some embodiments, the superconducting compounds of formula (I) can be compounds of formula (V): (BₓB′₁₋ₓ)ᵣZ′_{q}MₚA_{y}A′ₛ (V), in which B, Z′, M, A, A′, x, r, q, p, y, and are defined above. In some embodiments, a subset of superconducting compounds of formula (V) are those in which B is K or Rb, B; is Ba, Z′ is Y, M is Cu, A is O, and A′ is F, x is a number of 0.2 to 1, r is a number of 1 to 5, q is a number of 1 to 4, p is a number of 1 to 5, y is a number of 2 to 7, and s is a number of 0.3 to 4. Examples of such compound include Y₂Rb_{4.5}CuO_{3.5}F_{3.5}, Y_{1.5}Rb₃CuO₃F₃, Y₂Rb₃Cu₂F₄O₄, Y_{2.5}RbCu_{2.5}O₄F_{1.5}, Y₄RbCu₂O₇F_{0.3}, YRb₂Cu_{2.5}O₄F, YBa_{1.5}K_{0.25}Cu₂O_{3.5}F_{0.25}, YBa₂KCu₄O₆F_{0.5}, Y₃Ba₂KCu₂O₆F_{0.5}, Y_{1.5}BaKCu_{1.5}O₃F₂, and Y₂KCu₅O₄F_{1.5}.

In some embodiments, B′ is a metal ion having a first atomic number, Z′ is a metal ion having a second atomic number, and the second atomic number is smaller than the first atomic number. For example, B′ can be a metal ion containing Sr or Ba and Z′ can be a metal ion containing Ca.

In some embodiments, x in formula (I) ranges from 0.1 to 1 (e.g., from 0.2 to 1, from 0.3 to 1, from 0.4 to 1, from 0.5 to 1, from 0.55 to 1, from 0.6 to 1, from 0.65 to 1, from 0.7 to 1, from 0.75 to 1, from 0.8 to 1, from 0.85 to 1, from 0.9 to 1, from 0.95 to 1, from 0.97 to 1, from 0.98 to 1, or from 0.99 to 1). In some embodiments, x in formula (I) is 1. Without wishing to be bound by theory, it is believed that increasing the value of x can increase the critical temperature (Tc) of a superconducting compound of formula (I) as an increasing amount of the B′ ion (i.e., alkaline earth metal ions or rare earth metal ions) in the crystal structure in the compound of formula (I) is replaced by the B ion (i.e., an alkali metal ion).

In some embodiments, t in formula (I) ranges from 0.1 to 1 (e.g., from 0.2 to 1, from 0.3 to 1, from 0.4 to 1, from 0.5 to 1, from 0.6 to 1, from 0.7 to 1, from 0.8 to 1, from 0.9 to 1, from 0.95 to 1, from 0.98 to 1, or from 0.99 to 1). In some embodiments, t in formula (I) is 1. Without wishing to be bound by theory, it is believed that increasing the value of t (e.g., when t is above 0.5) can increase Tc of a superconducting compound of formula (I) as an increasing amount of the Z′ ion (i.e., alkaline earth metal ions or rare earth metal ions) in the crystal structure in the compound of formula (I) is replaced by the Z ion (i.e., an alkali metal ion).

In some embodiments, n in formula (I) can be any number (e.g., an integer or a non-integer) from 0 to 3. For example, n can be any number from 0.1 to 2.9 (e.g., from 0.2 to 2.8, from 0.3 to 2.7, from 0.4 to 2.6, from 0.5 to 2.5, from 0.6 to 2.4, from 0.7 to 2.3, from 0.8 to 2.2, from 0.9 to 2.1, from 1 to 2, from 1.1 to 1.9, from 1.2 to 1.8, from 1.3 to 1.7, from 1.4 to 1.6, or 1.5).

In some embodiments, m in formula (I) can be any number (e.g., an integer or a non-integer) from 0 to 6. For example, m can be any number from 0.1 to 5.9 (e.g., from 0.2 to 5.8, from 0.3 to 5.7, from 0.4 to 5.6, from 0.5 to 5.5, from 0.6 to 5.4, from 0.7 to 5.3, from 0.8 to 5.2, from 0.9 to 5.1, from 1 to 5, from 1.1 to 4.9, from 1.2 to 4.8, from 1.3 to 4.7, from 1.4 to 4.6, from 1.5 to 4.5, from 1.6 to 4.4, from 1.7 to 4.3, from 1.8 to 4.2, from 1.9 to 4.1, from 2 to 4, from 2.1 to 3.9, from 2.2 to 3.8, from 2.3 to 3.7, from 2.4 to 3.6, from 2.5 to 3.5, from 2.6 to 3.4, from 2.7 to 3.3, from 2.8 to 3.2, from 2.9 to 3.1, or 3). In some embodiments, the sum of n and m is an integer.

In some embodiments, r in formula (I) can be any number (e.g., an integer or a non-integer) from 1 to 8. For example, r can be any number from 1.1 to 7.9 (e.g., from 1.2 to 7.8, from 1.3 to 7.7, from 1.4 to 7.6, from 1.5 to 7.5, from 1.6 to 7.4, from 1.7 to 7.3, from 1.8 to 7.2, from 1.9 to 7.1, from 2 to 7, from 2.1 to 6.9, from 2.2 to 6.8, from 2.3 to 6.7, from 2.4 to 6.6, from 2.5 to 6.5, from 2.6 to 6.4, from 2.7 to 6.3, from 2.8 to 6.2, from 2.9 to 6.1, from 3 to 6, from 3.1 to 5.9, from 3.2 to 5.8, from 3.3 to 5.7, from 3.4 to 5.6, from 3.5 to 5.5, from 3.6 to 5.4, from 3.7 to 5.3, from 3.8 to 5.2, from 3.9 to 5.1, from 4 to 5, from 4.1 to 4.9, from 4.2 to 4.8, from 4.3 to 4.7, from 4.4 to 4.6, or 4.5).

In some embodiments, q in formula (I) can be any number (e.g., an integer or a non-integer) from 0 to 6. For example, q can be any number from 0.1 to 5.9 (e.g., from 0.2 to 5.8, from 0.4 to 5.6, from 0.6 to 5.4, from 0.8 to 5.2, from 1 to 5, from 1.2 to 4.8, from 1.4 to 4.6, from 1.6 to 4.4, from 1.8 to 4.2, from 2 to 4, from 2.2 to 3.8, from 2.4 to 3.6, from 2.6 to 3.4, or from 2.8 to 3.2).

In some embodiments, p in formula (I) can be any number (e.g., an integer or a non-integer) from 0 to 7. For example, p can be any number from 0.1 to 6.9 (e.g., from 0.2 to 6.8, from 0.4 to 6.6, from 0.6 to 6.4, from 0.8 to 6.2, from 1 to 6, from 1.2 to 5.8, from 1.4 to 5.6, from 1.6 to 5.4, from 1.8 to 5.2, from 2 to 5, from 2.2 to 4.8, from 2.4 to 4.6, from 2.6 to 4.4, from 2.8 to 4.2, from 3 to 4, from 3.2 to 3.8, from 3.4 to 3.6, or 3.5).

In some embodiments, s in formula (I) can be any number (e.g., an integer or a non-integer) from 0 to 20. For example, s can be any number from 1 to 19 (e.g., from 1.5 to 18.5, from 2 to 18, from 2.5 to 17.5, from 3 to 17, from 3.5 to 16.5, from 4 to 16, from 4.5 to 15.5, from 5 to 15, from 5.5 to 14.5, from 6 to 14, from 6.5 to 13.5, from 7 to 13, from 7.5 to 12.5, from 8 to 12, from 8.5 to 11.5, from 9 to 11, from 9.5 to 10.5, or 10).

In some embodiments, y in formula (I) can be any number (e.g., an integer or a non-integer) from 0 to 20. For example, y can be any number from 1 to 19 (e.g., from 1.5 to 18.5, from 2 to 18, from 2.5 to 17.5, from 3 to 17, from 3.5 to 16.5, from 4 to 16, from 4.5 to 15.5, from 5 to 15, from 5.5 to 14.5, from 6 to 14, from 6.5 to 13.5, from 7 to 13, from 7.5 to 12.5, from 8 to 12, from 8.5 to 11.5, from 9 to 11, from 9.5 to 10.5, or 10).

In some embodiments, the compounds of formula (I) can satisfy the following equation: x*r+t*q=s. In such embodiments, the number of the alkali metal ions (or the valence charges of the alkali metal ions) is identical to the number of the halogen anions (or the valence charges of the halogen ions). Without wishing to be bound by theory, it is believed that such a compound of formula (Ia) can form a structure that is more stable thermodynamically due to the formation of an alkali metal halogen salt layer.

In some embodiments, the compounds of formula (Ia) can satisfy the following equation: x*r=s. In such embodiments, the compounds of formula (Ia) can also satisfy the following equation: t*q=u. In such embodiments, the number of the alkali metal ions (or the valence charges of the alkali metal ions) is identical to the number of the halogen anions (or the valence charges of the halogen ions). Without wishing to be bound by theory, it is believed that such a compound of formula (Ia) can form a structure that is more stable thermodynamically due to the formation of an alkali metal halogen salt layer.

In some embodiments, a superconducting compound described herein is a crystalline metal oxide containing at least one transition metal ion (e.g., a Cu ion), at least one alkaline earth metal ion (e.g., a Sr or Ba ion) or at least one rare earth metal ion, and at least one chalcogen anion (e.g., O anion), in which from 10% to 100% of the at least one alkaline earth metal ion or at least one rare earth metal ion (i.e., in the crystal structure) is replaced by an alkali metal ion (e.g., an ion of Li, Na, K, Rb, or Cs) from 10% to 100% of the at least one chalcogen anion is replaced by a halogen anion (e.g., F or Cl). Examples of the crystalline metal oxides before modification include Bi₂Sr₂CaCu₂O_{y} (Bi2212), Bi₂Sr₂Ca₂Cu₃O_{y} (Bi2223), and YBa₂Cu₃O₇(YBCO). In some embodiments, the superconducting compound is a crystalline metal oxide described above in which from 20% to 100% (e.g., from 30% to 100%, from 40% to 100%, from 50% to 100%, from 60% to 100%, from 70% to 100%, from 80% to 100%, from 90% to 100%, from 95% to 100%, from 99% to 100%, or 100%) of the at least one alkaline earth metal ion or at least one rare earth metal ion in the crystal structure is replaced by an alkali metal ion. Without wishing to be bound by theory, it is believed that a superconducting metal oxide in which a higher amount (e.g., more than 50%) of an alkaline earth metal ion in its crystal structure is replaced by an alkali metal ion would exhibit a higher Tc based on the model described below. In some embodiments, the superconducting compound is a crystalline metal oxide described above in which from 10% to 90% (e.g., from 15% to 85%, from 20% to 80%, from 25% to 75%, from 30% to 70%, from 35% to 65%, from 40% to 60%, from 45% to 55%, or 50%) of the at least one chalcogen anion in the crystal structure is replaced by a halogen anion. Without wishing to be bound by theory, it is believed that a certain amount of chalcogen anion is replaced by a halogen anion can form a structure that is more stable thermodynamically due to the formation of an alkali metal halogen salt layer.

In some embodiments, the crystalline metal oxide described above can further include a post-transition metal ion (e.g., an ion of Bi or Tl) or a transition metal ion (e.g., a Hg ion), such as those described above. In some embodiments, the crystalline metal oxide described above can include a rare earth metal ion (e.g., Y), such as those described above.

In some embodiments, the crystalline metal oxide described above can include two or more (e.g., three or four) alkaline earth metal ions (e.g., Sr, Ba, and/or Ca ions). In such embodiments, only one of the alkaline earth metal ions can be replaced by an alkali metal ion or two or more of the alkaline earth metal ions can be replaced by alkali metal ions.

In some embodiments, when two or more alkaline earth metal ions in a crystalline metal oxide are replaced by two or more alkali metal ions, each alkaline earth metal ion can be replaced by any one of the two or more alkali metal ions.

In some embodiments, the crystalline metal oxide described above can include two or more (e.g., three or four) halogen anions (e.g., F, Cl, Br, and/or I anions). For example, in a compound of formula (Ia), A′ and A″ can be two different halogen anions.

In some embodiments, a superconducting compound described herein (e.g., a compound of formula (I)) is a compound having a crystal structure, where the crystal structure includes a plurality of cell units, at least 10% of the cell units include a cluster (e.g., a sub cell unit); the cluster includes a plurality of anions (e.g., O anions and/or halogen anions), a plurality of transition metal ions (e.g., Cu ions), and at least one alkali metal ion (e.g., ions of Li, Na, K, Rb, and Cs); each transition metal ion forms a covalent bond with at least one anion; the plurality of anions define a plane; the at least one alkali metal ion is located approximate to the plane; the distance between the at least one alkali metal ion and the plane is less than twice of the radius of the at least one alkali metal ion; and at least two of the plurality of anions have a distance of from 3.8 Å to 4.2 Å. In some embodiments, the at least two of the plurality of anions can have a distance of at least 3.8 Å (e.g., at least 3.85 Å, or at least 3.9 Å) and/or at most 4.2 Å (e.g., at most 4.15 Å, at most 4.1 Å, at most 4.05 Å, or at most 4 Å). In some embodiments, at least 20% (e.g., at least 30%, at least 40%, at least 50%, at least 60%, at least 70%, at least 80%, at least 90%, at least 95%, or at least 99%) of the cell units in the crystal structure include the cluster described above (which contains at least one alkali metal ion). In some embodiments, other anions and metal ions described above can be used in addition to the cluster to form a superconducting compound. For example, a charge reservoir layer or a doping mechanism (e.g., interstitial ions) can be included in addition to the cluster to form a superconducting compound.

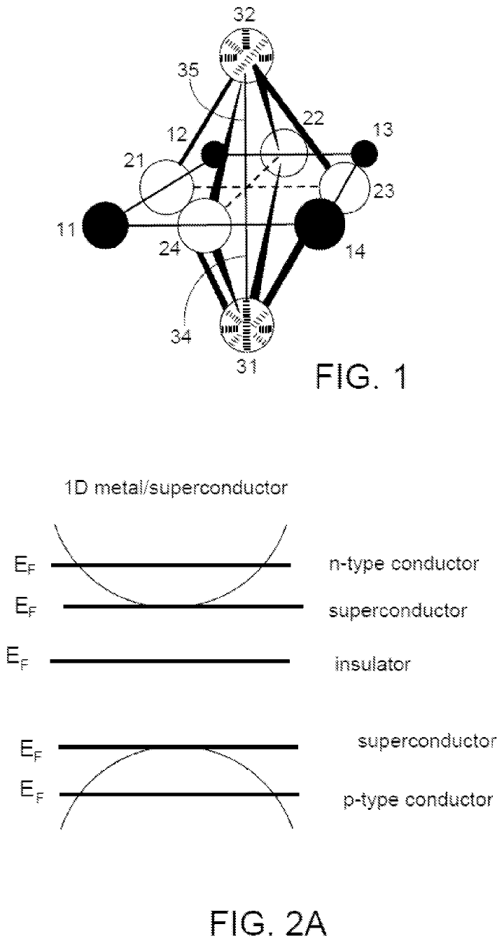

FIG. 1 illustrates a crystal structure that includes an exemplary cluster (i.e., an octahedral cluster) described above that includes four in-plane ions and two buffer ions (e.g., an alkali metal ion and an alkaline earth metal ion or a transition metal ion). As shown in FIG. 1, the cluster includes anions 21, 22, 23, and 24 (e.g., O anions), transition metal ions 11, 12, 13, and 14 (e.g., Cu ions), and two buffer ions 31 and 32, at least one of which is an alkaline metal ion (e.g., ions of Li, Na, K, Rb, and Cs). Note that halogen anions in the superconducting compounds described herein are not shown in FIG. 1 and the atoms drawn in FIG. 1 are for illustration purpose only and are not drawn to scale. Each of transition metal ions 11, 12, 13, and 14 forms a covalent bond with a neighboring anion. Transition metal ions 11, 12, 13, and 14 and anions 21, 22, 23, and 24 form a plane in which metal ions 11, 12, 13, and 14 are located at the vertices of the plane, and anions 21, 22, 23 and 24 are located at the edges of the plane. The distance 34 or 35 between the buffer ion 31 or 32 and the plane is less than twice of the radius of the buffer ion. In some embodiment, when alkali metal ion 31 is the same as the alkali metal ion 32, the distance 34 is substantially similar to the distance 35. The distance between two anions facing each other (i.e., the distance between anions 21 and 23 or the distance between anions 22 and 24) in the plane is from 3.8 Å to 4.2 Å. In some embodiment, ion 31 is an alkali metal ion and ion 32 is a different ion (e.g., an alkaline earth metal ion or a transition metal ion).

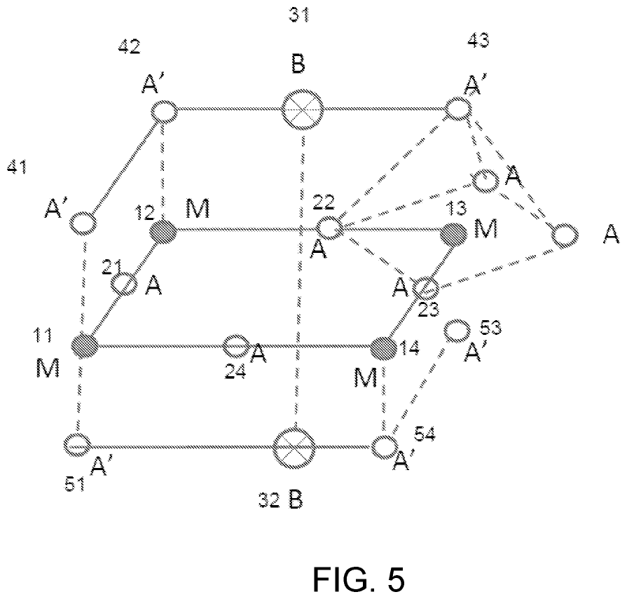

FIG. 5 illustrates a representative crystal structure of a superconducting compound containing halogen anions. Specifically, the crystal structure shown in FIG. 5 includes alternating MA (e.g., CuO) layers and BA′ (e.g., NaCl) layers, in which B, M, A, and A′ are defined above in connection with formula (I). As shown in FIG. 5, the crystal structure includes anions 21, 22, 23, and 24 (e.g., O anions and/or halogen anions), transition metal transition metal ions 11, 12, 13, and 14 (e.g., Cu ions), two alkaline metal ions 31 and 32 (e.g., ions of Li, Na, K, Rb, and Cs), and halogen anions 41, 42, 43, 51, 53, and 54. As shown in FIG. 5, at least one apical chalcogen anion (A) is replaced by the halogen anion (A′).

In some embodiments, a superconducting compound of formula (I) can include a cluster (e.g., a sub cell unit in the crystal structure of the compound) having a formula of BZMA₂, BZMA₂A′, B₂MA₂A′, BZ′MA₂, or BZ′MA₂A′, in which B, Z, Z′, M, A, and A′ are defined above.

Without wishing to be bound by theory, it is believed that the cluster described herein (e.g., a cluster having a structure of BZMA₂, BZMA₂A′, B₂MA₂A′, BZ′MA₂, or BZ′MA₂A′) is primarily responsible for the high Tc and superconducting activities/properties at a high temperature (e.g., at least about 150K). Thus, without wishing to be bound by theory, it is believed that all crystalline compounds (e.g., metal oxide crystalline compounds) having such a cluster would exhibit high Tc and superconducting activities/properties at a high temperature.

In some embodiments, a superconducting compound described herein includes at least 15% (e.g., at least 20%, at least 25%, at least 30%, at least 35%, at least 40%, at least 45%, at least 50%, at least 55%, at least 60%, at least 65%, at least 70%, at least 75%, at least 80%, at least 85%, at least 90%, at least 95%, at least 98%, at least 99%, or 100%) of cell units that have the cluster described above (e.g., such as that shown in FIG. 1) in its crystal structure. Without wishing to be bound by theory, it is believed that a superconducting compound containing a higher amount (e.g., more than 50%) of the cluster described above would exhibit a higher Tc based on the model described below. In some embodiments, a superconducting compound described herein further contains one or more clusters similar to that shown in FIG. 1 except that the alkali metal ion is replaced by an alkaline earth metal ion (e.g., Ca, Sr, or Ba) or a rare earth metal ion (e.g., La).

In some embodiments, a superconducting compound containing the cluster described above can further include a transition metal ion or a post-transition metal ion, such as the L ion in formula (I). Without wishing to be bound by theory, it is believed that additional anions attached to the L ion can be considered as doping ions for the cluster described above so as to render the plane formed by anions 21, 22, 23, and 24 conducting. Further, without wishing to be bound by theory, it is believed that such a doping effect can facilitate the formation of the superconductivity of the compound.

In some embodiments, the cluster described above can include only two anions, which have a distance of from 3.8 Å to 4.2 Å. In such embodiments, the other metal ions in the cluster can be located at any locations in space so as to keep the two anions at the above distance. Any reference to the plane formed by anions 21, 22, 23, and 24 defined above can now be replaced by the line connecting these two anions. In some embodiments, a superconducting compound having such a cluster (e.g., a sub cell unit in the crystal structure of the compound) can have a formula of BMA₂, in which B, M, and A are defined above.

In some embodiments, the superconducting compounds described herein are substantially pure. For example, the superconducting compounds can have a purity of at least 50% (e.g., at least 60%, at least 70%, at least 80%, at least 90%, at least 95%, at least 98%, at least 99%, or 100%).

In general, the compounds described herein can be superconductors (e.g., capable of carrying superconductive current) at a relatively high temperature under atmospheric pressure. In some embodiments, the superconducting compounds described herein can be a superconductor at the temperature of at least 150K (e.g., at least 160K, at least 170K, at least 180K, at least 190K, at least 200K, at least 210K, at least 220K, at least 230K, at least 240K, at least 250K, at least 260K, at least 270K, at least 273K, at least 283K, at least 293K, at least 300K, at least 320K, at least 340K, at least 360K, at least 380K, or at least 400K) and/or at most about 500K (e.g., at most about 480K, at most about 460K, at most about 450K, at most about 440K, at most about 420K, or at most about 400K). In some embodiments, the superconducting compounds described herein can have Tc of at least 150K (e.g., at least 160K, at least 170K, at least 180K, at least 190K, at least 200K, at least 210K, at least 220K, at least 230K, at least 240K, at least 250K, at least 260K, at least 270K, at least 273K, at least 283K, at least 293K, at least 300K, at least 320K, at least 340K, at least 360K, at least 380K, or at least 400K) and/or at most 500K (e.g., at most 480K, at most 460K, at most 450K, at most 440K, at most 420K, or at most 400K). Without wishing to be bound by theory, it is believed that crystalline compounds having the cluster structure described above can exhibit a high Tc based on the model described below.

In some embodiments, this disclosure features a composition containing a superconducting compound described herein. In such embodiments, the composition can contain at least 1% (e.g., at least 2%, at least 3%, at least 5%, at least 10%, at least 20%, at least 30%, at least 40%, or at least 50%) and/or at most about 99.9% (e.g., at most 99%, at most 98%, at most 95%, at most 90%, at most 80%, at most 70%, at most 60%, or at most 50%) of the superconducting compound.

In some embodiments, this disclosure features a method of forming a superconducting compound. The method can include (1) mixing at least one metal oxide (e.g., a crystalline metal oxide) with at least first and second salts to form a mixture, in which the metal oxide contains at least one transition or post-transition metal cation (e.g., a Cu, Y, Bi cation), the first salt is an alkali metal halogen salt containing an alkali metal cation (e.g., an ion of Li, Na, K, Rb, or Cs) and a halogen anion (e.g., F, Cl, Br, or I), and the second salt contains an alkaline earth or rare earth metal cation, and (2) sintering the mixture at an elevated temperature to form a crystalline compound containing the alkali metal ion and the halogen anion. In some embodiments, the atomic ratio between the alkali metal cation and the alkaline earth or rare earth metal cation is at least 1:1 (e.g., 2:1, 3:1, 5:1, or 10:1). In some embodiments, the at least one metal oxide can also include an alkaline earth or rare earth metal cation. Examples of metal oxides that can be used as starting materials to prepare the superconducting compounds described herein include Y₂O₃, CuO, Bi₂O₃, CaO, BaO, and SrO. Examples of suitable alkali metal halogen salts that can be used as starting materials to prepare the superconducting compounds described herein include KF, KCl, NaF, NaCl, RbF, RbCl, CsF, and CsCl. In some embodiments, the second salt containing an alkaline earth metal cation (e.g., a Ca, Ba, or Sr cation) and at least one carbonate anion. Examples of such salts include CaCO₃, BaCO₃, and SrCO₃.

In some embodiments, the preparation method described herein can include (1) mixing at least one metal oxide (e.g., a crystalline metal oxide) with an alkali metal halogen salt containing an alkali metal cation (e.g., an ion of Li, Na, K, Rb, or Cs) and a halogen anion (e.g., F, Cl, Br, or I) to form a mixture, in which the at least one metal oxide contains at least one transition or post-transition metal ion (e.g., a Cu, Y, or Bi ion) and at least one alkaline earth metal ion (e.g., a Ca, Sr, or Ba ion), and the atomic ratio between the alkali metal cation and the at least one alkaline earth metal ion is at least 1:1; and (2) sintering the mixture at an elevated temperature to form a crystalline compound containing the alkali metal ion. Suitable crystalline metal oxides that can be used as starting materials to prepare the superconducting compounds described herein include for example Bi2212, YBCO, Bi2223, Tl2212, Tl2223, Hg1201, Hg1212, and Hg1223. Thus, in some embodiments, the superconducting compounds of formula (I) can be prepared by the above manufacturing method using a corresponding metal oxide and a suitable alkali metal halogen salt (e.g., KF, KCl, NaF, NaCl, RbF, RbCl, CsF, or CsCl) as starting materials.

In some embodiments, when the superconducting compounds of formula (I) contain an element D, the element D can be introduced into the superconducting compounds by adding a salt (e.g., an alkali metal salt) containing element D in the mixture described in step (1) above. Suitable salts containing element D that can be used to prepare the superconducting compounds described herein include for example K₂CO₃, K₂SiO₃, K₂B₄O₇, Rb₂CO₃, Rb₂SiO₃, Cs₂CO₃, Cs₂SiO₃, KHCO₃, RbHCO₃ or CsHCO₃. For example, to prepare the superconducting compounds of formula (I) containing an element D where D is carbon, an alkali metal salt containing carbon (e.g., K₂CO₃, Rb₂CO₃, or Cs₂CO₃) can be used in step (1) described above. In addition, the superconducting compounds described herein in which D is carbon can be prepared by sintering a crystalline metal oxide and an alkali metal salt under a flow of CO₂ to induce incorporation of carbon in the structure. It is believed that carbon atoms, if imbedded in the crystal structure, can facilitate the incorporation of alkali metal ions in the crystal.

In some embodiments, the atomic ratio (i.e., the molar ratio) between the alkali metal ion in the alkali metal salt and the at least one alkaline earth metal ion in the metal oxide is at least 1.3:1 (e.g., at least 1.5:1, at least 1.7:1, at least 2:1, at least 2.3:1, at least 2.5:1, at least 2.7:1, at least 3:1, at least 4:1, at least 5:1, at least 6:1, at least 7:1, at least 8:1, at least 9:1, at least 10:1, at least 11:1, at least 12:1, at least 13:1, at least 14:1, at least 15:1, or at least 16:1). In some embodiments, when the metal oxide starting material contains two or more alkaline earth metal ions, the atomic ratio described above can be between the alkali metal ion in the alkali metal salt and one of the two or more alkaline earth metal ions in the metal oxide. Without wishing to be bound by theory, it is believed that using an excess amount (e.g., more than 1:1 atomic ratio) of an alkali metal salt in the method described above can facilitate replacement of the alkaline earth metal ion in the crystal structure of the metal oxide compound by the alkali metal ion. Further, without wishing to be bound by theory, it is believed that a superconducting metal oxide containing a higher amount of an alkali metal ion in its crystal structure would exhibit a higher Tc based on the model described below.

In general, the sintering temperature used in the method described can depend on various factors such as the structure of the compound to be synthesized and their melting temperatures. In some embodiments, the sintering temperature is at least 300° C. (e.g., at least 400° C., at least 500° C., at least 600° C., at least 700° C., at least 750° C., or at least 800° C.) and/or at most 1200° C. (e.g., at most 1100° C., at most 1000° C., at most 900° C., at most 850° C., at most 820° C., or at most 800° C.). The sintering time (or the dwelling time) can be at least 20 hours (e.g., at least 30 hours, at least 40 hours, at least 50 hours, at least 100 hours, or at least 150 hours) and/or at most 300 hours (e.g., at most 280 hours, at most 250 hours, at most 220 hours, at most 200 hours, or at most 150 hours).

In some embodiments, the mixture of a crystalline metal oxide and an alkali metal salt can be sintered at a first temperature for a first period of time and then sintered at a second temperature different from the first temperature for a second period time. In some embodiments, the second temperature can be higher than the first temperature. The first or second temperature can be at least 750° C. (e.g., at least 760° C., at least 770° C., at least 780° C., at least 790° C., at least 800° C., or at least 810° C.) and/or at most 850° C. (e.g., at most 840° C., at most 830° C., at most 820° C., at most 810° C., or at most 800° C.).

In some embodiments, the superconducting compounds described herein or one or more layer of its crystal structure can be prepared by using other methods known in the art, such as pulsed laser deposition (PLD), atomic layer deposition (ALD), molecular beam epitaxy (MBE), and metal-organic chemical vapor deposition (MOCVD). Examples of the MBE methods that can be used to prepare the superconducting compounds described herein have been described in WO 2019/116103, the entire contents of which are incorporated herein by reference. For example, a superconducting compound described herein BMAA′ (e.g., NaCuOF) can be prepared by using PLD or MBE methods known in the art.

Without wishing to be bound by theory, the inventor believes that the high temperature superconducting compounds and methods of making such compounds are based on the principles and model described in more detail below.

It is believed that superconductive behavior of charge carriers arises as a result of nearly degenerate dispersion relation ε(k) of a material, at proximity to the Fermi level thereof. Accordingly, the complete many-body Hamiltonian is simplified to a residual Hamiltonian, formally similar to the reduced Hamiltonian postulated by the well-known BCS model [Bardeen, et. al., Phys. Rev. 108, 1175 (1957)], while maintaining a connection between prediction of superconducting behavior and electronic and chemical structure of a corresponding material composition through the Schrodinger equation. More specifically, the nearly degenerate dispersion relation may be a result of little overlap between electronic states. This allows prediction of superconducting behavior as a result of calculation of electronic states in small atomic clusters providing reasonable accuracy of meV (milli electron Volt).

Thus, it is believed that materials suspected as providing superconducting behavior may be identified by the use of energy state computation for energies of at least two electronic states associated with a corresponding atomic cluster. Such an atomic cluster generally includes a plurality of atoms of at least one candidate element/species being neutral atoms, cations and anions. The calculation utilizes geometrical characterization of the atomic structure including distances between the elements of the cluster. It should be noted that the computation may generally include variation of one or more ionic species and distances and which may imply that certain atoms of the cluster are to be replaced with others. The frontier molecular orbitals of the cluster should be identified by the appropriate calculation and such frontier molecular orbitals having relatively low overlap may be detected. The frontier molecular orbitals generally relate to Highest Occupied Molecular Orbital (HOMO) and the Lowest Unoccupied Molecular Orbital (LUMO).

Additionally, the band structure of a similar superconducting compound can be calculated to provide an estimation of the corresponding Fermi level. The atomic cluster may be varied to provide that the Fermi level lays in proximity with the energetic level of the identified low overlap frontier molecular orbitals.

The compound described by the calculated atomic cluster may be determined as having high probability to exhibit superconducting behavior if the selected low overlap frontier molecular orbitals show that bonding and anti-bonding energies are different by less than about 150 meV (e.g., less than 100 meV, or preferably less than 50 meV) and/or more than 1 meV (e.g., more than 5 meV or more than 10 meV). Usually such atomic clusters have high separation between adjacent energy levels. It is believed that one should look for such cases where the highest levels of the cluster, preferably the ground state and the first excited state are intrinsically nearly degenerate.

In some embodiments, the inventor believes that the following analysis provides a basis for identifying a superconducting material and a method of making such a superconducting material. See Gatt, Journal of Superconductivity and Novel Magnetism, 33, 1345.

Starting with a full Hamiltonian expression including the kinetic energy, the phonon part, the electron-phonon interaction and the electron-electron interaction:

$$H = {ε}_{0} {\sum }_{k} {c}_{k}^{†} {c}_{k} + {\sum }_{k} ( {ε}_{k} - {ε}_{0} ) {c}_{k}^{†} {c}_{k} + {\sum }_{q} {ω}_{q} ( {a}_{q}^{†} {a}_{q} + \frac{1}{2} ) + {\sum }_{q , k} {M}_{q} {c}_{k + q}^{†} {c}_{k} ( {a}_{q}^{†} + {a}_{- q} ) + {\sum }_{q , k , {k}^{′}} v ( q ) {c}_{k + q}^{†} {c}_{{k}^{′} + q}^{†} {c}_{{k}^{′}} {c}_{k} \qquad ( 1 )$$

where ε₀=μ is the chemical potential (to be determined); εₖ is the normal quasiparticle energy;

$${c}_{k}^{†}$$

and cₖ are electronic creation and destruction operators respectively;

$${a}_{q}^{†}$$

and a_{q} are phononic creation and destruction operators respectively; ω_{q} is the phonon frequency, M_{q} is an electron-phonon matrix element and v(q) is a screened Coulombic potential. The Hamiltonian of equation (1) is simplified utilizing the standing wave assumption:

$${∇}_{k} ε = 0 \qquad ( 2 )$$

This assumption states that all of the electronic k states are degenerate, i.e. having similar energy. Additionally, based on the assumption that the second term in equation (1) is a small perturbation, the following transformation introduces renormalized phonon operators:

$${A}_{q} = {a}_{q} + \frac{{M}_{q}^{*}}{{ω}_{q}} {\sum }_{k} {c}_{k - q}^{+} {c}_{k} \qquad ( 3 )$$

Using the standing wave assumption for electronic density operator provides:

$${ρ}_{1} ( q , t ) = {\sum }_{k} {c}_{k - q}^{+} ( t ) {c}_{k} = \sum {c}_{k - q}^{+} {e}^{\frac{i}{ℏ} {ε}_{0} t} {e}^{- \frac{i}{ℏ} {ε}_{0} t} = {ρ}_{1} ( q ) \qquad ( 4 )$$

and similarly the square density operator:

$${ρ}_{2} ( q , t ) = {\sum }_{k , {k}^{′}} {c}_{k - q}^{+} ( t ) {c}_{{k}^{′} + q}^{+} ( t ) {c}_{{k}^{′}} ( t ) {c}_{k} ( t ) = {ρ}_{2} ( q ) \qquad ( 5 )$$

indicating that the electronic density ρ₁(q) is a constant of the motion and that A_{q} retains the canonical relations (boson commutation relations):

$$[ {A}_{q} , {A}_{{q}^{′}}^{+} ] = {δ}_{q , {q}^{′}} , [ {A}_{q} , {A}_{{q}^{′}}^{+} ] = 0 = [ {A}_{q} , {A}_{{q}^{′}} ] \qquad ( 6 )$$

The renormalized phonon density expression provides:

$${\sum }_{q} {ω}_{q} {A}_{q}^{+} {A}_{q} = {\sum }_{q} {ω}_{q} {a}_{q}^{+} {a}_{q} + {\sum }_{q} {M}_{q} ( {a}_{q} + {a}_{q}^{+} ) {\sum }_{k} {c}_{k + q}^{+} {c}_{k} ++ \frac{{\vert {M}_{q} \vert}^{2}}{{ω}_{q}} ( {\sum }_{k} {c}_{k - q}^{+} {c}_{k} ) ( {\sum }_{{k}^{′}} {c}_{{k}^{′} + q}^{+} {c}_{{k}^{′}} ) \qquad ( 7 )$$

using

$${M}_{- q}^{*} = {M}_{q}$$

and rearranged the summation order.

Using the renormalized phonon operator in the Hamiltonian of equation (1), the Hamiltonian can be diagonalized under the standing wave condition of equation (2) while neglecting the kinetic energy term as a perturbation:

$${H}_{{0}^{=}} {ε}_{0} N + {\sum }_{q} {ω}_{q} ( {A}_{q}^{+} {A}_{q} + \frac{1}{2} ) + {\sum }_{q} ( v ( q ) - \frac{{\vert {M}_{q} \vert}^{2}}{{ω}_{q}} ) {ρ}_{2} ( q ) \qquad ( 8 )$$

This provides pairing correlation ρ₂(q) as a result of the standing wave assumption (2) and canonical transformation (3).

The kinetic energy term can be treated as a perturbation

$${H}_{1} = {\sum }_{k} ( {ε}_{k} - {ε}_{0} ) {c}_{k}^{+} {c}_{k} \qquad ( 9 )$$

i.e. H=H₀+H₁. After diagonalizing the standing waves Hamiltonian H₀, the electronic residue remains in the equation:

$${H}_{e} = {\sum }_{k} ( {ε}_{k} - {ε}_{0} ) {c}_{k}^{+} {c}_{k} + {\sum }_{q} ( v ( q ) - \frac{{\vert {M}_{q} \vert}^{2}}{{ω}_{q}} ) {ρ}_{2} ( q ) \qquad ( 10 )$$

in resemblance to the well known reduced BCS Hamiltonian [Bardeen, et al., Phys. Rev. 108, 1175 (1957)]. The anticipated quasi-particle interactions with the phonons and among themselves are neglected in the low quasi-particle density (low temperature) limit. Following BCS, these interactions can be considered to be similar as in the normal state. It should be noted that no pairing is assumed. It arises from the assumption of standing wave behavior.

Based on the BCS theory,

$$〈 Ψ \vert {H}_{e} - μ N - {\sum }_{q} {λ}_{q} {ρ}_{2} ( q ) \vert Ψ 〉 = {\sum }_{k} 2 {ε}_{k} {\vert {v}_{k} \vert}^{2} + {\sum }_{q} ( v ( q ) - \frac{{\vert {M}_{q} \vert}^{2}}{{ω}_{q}} - {λ}_{q} ) {ρ}_{2} ( q ) \qquad ( 11 )$$

where λ_{q} is a Lagrange multiplier relating to the constraint of constant square density:

$$\frac{\partial }{\partial t} {ρ}_{2} ( q ) = 0 \qquad ( 12 )$$

Equation (11) derives an energy gap, which is formally similar to that predicted by BCS:

$$\begin{matrix}{Δ}_{k} = \frac{1}{2} {\sum }_{{k}^{′}} ( {V}_{kk} - {λ}_{q} ) \frac{{Δ}_{k}}{{E}_{k}} & {E}_{k} = \sqrt{{ξ}_{k}^{2} + {Δ}_{k}^{2}}\end{matrix} \qquad ( 13 )$$

The BCS theory is therefore found to be embedded in the standing wave theory. The ground state is found to be a condensate of non-dispersing standing electronic wave functions. The excited states are dispersive quasi-particle electronic states (bogolons). It also should be noted that the electronic operators c⁺ and c in equation (9) are understood as perturbed standing wave states.

Additionally, the electrodynamics of superconducting materials can be derived from the London equations. According to the present disclosure, the London equations may provide microscopic relation between standing wave electrons and the vector potential, without requiring the rigidity of the many-body wave function.

One can start with the single standing wave electron function:

$${φ}_{a} ( r , t ) = \frac{1}{\sqrt{2}} ϕ ( r ) ( {e}^{ia ( r )} + {e}^{- ia ( r )} ) {e}^{\frac{i}{ℏ} ε t} \qquad ( 14 )$$

and utilize the calculation below, while not requiring pairing, to derive the London equations. Since electron pairs are generally favored energetically, as appears from the diagonalized Hamiltonian H₀, a single pair wave function can be obtained. This can preserve the 2e charge observed experimentally. The superconducting standing wave states at T=0, provided by an electron pair thus provides:

$$Ψ ( {r}_{1} , {r}_{2} , t ) = C φ ( {r}_{1} , t ) φ ( {r}_{2} , t ) \vert ↑ ↓ 〉 \qquad ( 15 )$$

where C is any complex constant, |↑↓ [symbol] denotes a singlet state, and φ(r,t) is a standing wave function given by equation (14). The spatial part of φ(r,t) is a real function with respect to a vector potential in the London Gauge, i.e., assuming ∇·A=0, A⊥=0 at the surface of an isolated body. The corresponding probability current is:

$$J ( r , t ) = Re [ {Ψ}^{*} ( \frac{ℏ}{im} ∇ - \frac{q}{mc} A ) Ψ ] \qquad ( 16 )$$

where J(r,t) is the current density as a function of location (r) and time (t), Re states that the real part of the formula is considered, Ψ and Ψ* are the electron pair wave function and its conjugate, m is the electron mass, q is the electron charge, ℏ is Planck's constant divided by 2π, and i=square root of (−1). Equation (16) can be expanded to provide:

$${Ψ}^{*} \frac{ℏ}{im} ∇ Ψ = {CC}^{*} \frac{ℏ}{im} φ ( {r}_{t} , t ) φ ( {r}_{2} , t ) [ {∇}_{1} φ ( {r}_{1} , t ) φ ( {r}_{2} , t ) + φ ( {r}_{1} , t ) {∇}_{2} φ ( {r}_{2} , t ) ] \qquad ( 17 )$$

such that

$$Re [ {Ψ}^{*} \frac{ℏ}{im} ∇ Ψ ] = 0 \qquad ( 18 )$$

$$and$$

$$J ( r , t ) = - \frac{q}{mc} A {\vert Ψ \vert}^{2} \qquad ( 19 )$$

The above provides that the London equation appear as a single particle microscopic property. It is a linear relation between the probability current of each superconducting pair and the vector potential. Thus, all electron pairs obey the London equations individually. The total current is given by a summation over these states. Therefore, the relation between the total electric current and the vector potential is given by the well-known non-local Pippard integral, giving the macroscopic London equations. Additionally, it should be noted that derivation of the London equations requires no assumption on macroscopic coherence of any kind. It should also be noted that the same derivation applies to a single standing wave electron. The pairing is not required to derive the London relation, it is a result (by means of ρ2) of the same standing wave assumption.

The Pippard integral now appears as a summation over standing wave states. A summation carried over the single electron probability currents to get the total current. Therefore, the coherence length is the reciprocal of the k-state summation appearing in ρ2 giving the non-local length scale over which the relation between the current and the vector potential is maintained. Due to Pippard, the coherence length gives an estimation of the critical temperature. Therefore, the k-space extension of the flat band region at the Fermi level gives an estimate of the critical temperature. A more accurate estimation of the critical temperature will be given by estimating the low dispersive volume in k-space at the proximity of the Fermi level. This will determine the parameter ρ2 and therefore Δ and therefore Tc.

Other potentials should be related to the London potential by a gauge transformation: A′=A+∇χ, where χ(r) may be any scalar function. The corresponding transformation of the wave function is then:

$${Ψ}^{′} = Ψ {e}^{i \frac{q}{ℏ c} χ ( r )} \qquad ( 20 )$$

and the current density is

$$J ( r , t ) = Re [ {Ψ}^{{′}^{*}} ( r , t ) ( \frac{ℏ}{im} ∇ - \frac{q}{mc} A ( r , t ) ) {Ψ}^{′} ( r , t ) ] = \frac{q}{mc} ∇ χ ( r ) {\vert {Ψ}^{′} \vert}^{2} - \frac{q}{mc} A ( r , t ) {\vert {Ψ}^{′} \vert}^{2} \qquad ( 21 )$$

providing again:

$$J ( r , t ) = - \frac{q}{mc} A ( r , t ) {\vert Ψ \vert}^{2} \qquad ( 22 )$$

Thus, the present disclosure provides that the rigidity of the many-body wave function, which is maintained by the energy gap according to the BCS treatment, is replaced by a single-body relation that is the property of any real wave function in the London gauge. Thus, the long range coherence, explained as the phase rigidity of the order parameter, can now be understood as merely reflecting this single-electron behavior.

Without wishing to be bound by theory, it is believed that the standing waves theory provides a simple understanding of the gauge symmetry breaking observed in superconductors. This broken symmetry may arise from breaking of the periodic boundary conditions for the electronic wave function in the normal state, allowing for arbitrary phase of the wave function. The standing wave boundary condition is generally driven from the bulk, by the relaxation of the phonon cloud (or other boson for that matter) against a standing electronic wave function (eq. 3-8). This is the proposed physical understanding of gauge symmetry breaking in the case of superconductivity. Grain boundaries and other defects may only assist superconductivity by supporting these standing wave states.

The single electronic current in the standing waves treatment is not divergence free and can be described as:

$$∇ \cdot J ( r , t ) = - \frac{q}{mc} A ( r , t ) \cdot ∇ {\vert Ψ ( r , t ) \vert}^{2} \qquad ( 23 )$$

being in accordance with a BCS-like ground state where standing wave pair states are constantly created and destroyed. Again, J(r,t) here is the probability current of a single pair, while the total current is assumed to provide:

$$∇ \cdot {J}_{total} + \frac{d ρ}{dt} = 0 \qquad ( 24 )$$

Utilizing again the assumption of zero dispersion:

$$\frac{d ρ}{dt} = \frac{d}{dt} {\sum }_{q} {ρ}_{q} = \frac{d}{dt} {\sum }_{k , q} {c}_{k + q}^{+} ( t ) {c}_{k} ( t ) = \frac{d}{dt} {\sum }_{k , q} {c}_{k + q}^{+} {e}^{\frac{- i}{ℏ} {ε}_{0} t} {c}_{k} {e}^{\frac{i}{ℏ} {ε}_{0} t} = 0 \qquad ( 25 )$$

provides that the total current in an isolated body is divergence-free.

From equation (23), it is shown that in a superconductor, the surface current should be divergence free, requiring that the wave function ∇|ψ(r,t)|=0 is null at the surface of the superconductor (in the London gauge).

The understanding of the present disclosure may also be derived from the quasi-classical point of view. In the quasi-classical picture, a standing wave is a wave-packet with group velocity v_{g}=0. The magnetic force acting on such wave-packet is F=v_{g}×B=0. Therefore, the semi-classical standing wave state is not affected by magnetic fields. However, it is known that vector potential acting of the wave-packet affects the phase of the single electron wave function as shown by the Aharonov-Bohm effect. A super-current phenomenon is therefore a current of all the super-electrons as appropriate wave-packets, acting not as a collective effect due to coherence of the many-body wave function, but simply as a phase current. Such super-current, therefore, does not interfere with the electron-phonon relaxation, being a uniform current for all super-electrons.

The Pippard integral comes from the relation between the vector potential and the macroscopic current. In order to get the macroscopic current, one needs to integrate over all the standing wave k-states. This is affecting real space integration over a region on the order of the coherence length.

As a result of the above understanding, the present disclosure provides a general rule which can identify new and improved superconducting materials. This is generally similar to the Wilson's rule for metals and insulators. According to Wilson, a simple rule differentiates between insulating and conducting material by locating the Fermi level with respect to the energetic band structure of the material. If the Fermi level cuts the energy band, the material is a metal; if it falls in the gap, the material is an insulator. Additionally, if the gap is on the order of the thermal energy, the material is a semiconductor.

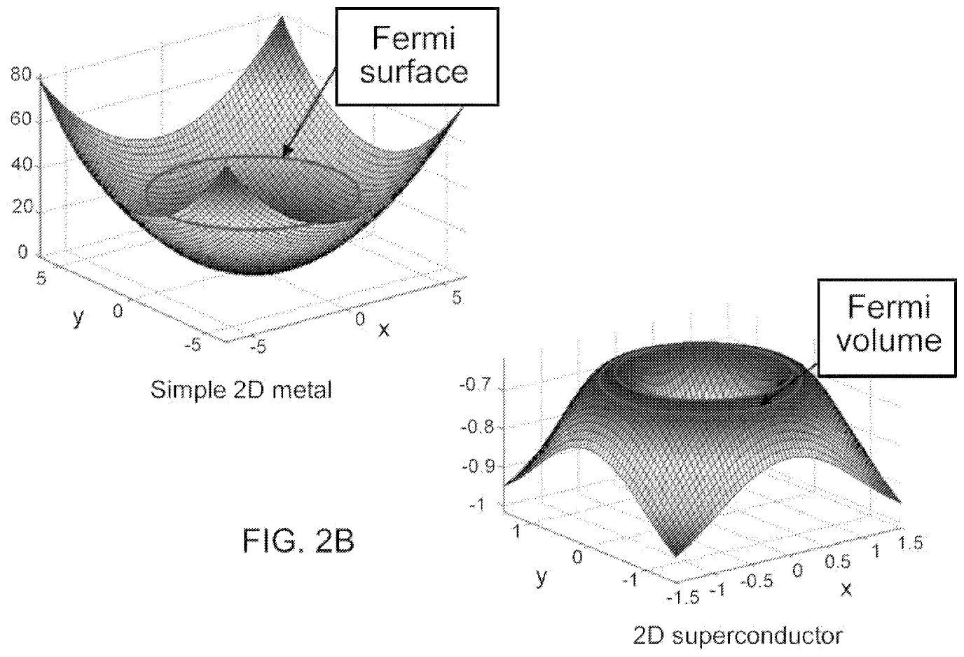

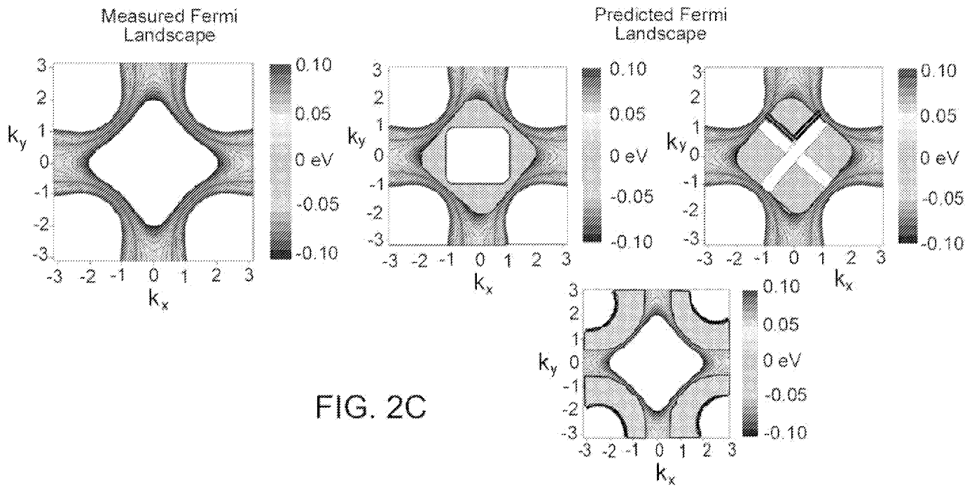

Based on the above understanding, the present disclosure provides the general principle that a superconductor behaves as a metal where the Fermi level is in the proximity (e.g., at most 50 meV) of a very shallow region of the energy levels ε(k). This condition complies with the above treatment of the kinetic energy term in equation (9) as a perturbation. Additionally, this allows for the above diagonalization of the Hamiltonian H₀. FIGS. 2A-2C illustrate schematically the relationship among the energy band of a material, its Fermi level and its corresponding conductance according to the Wilson rule and the present disclosure.

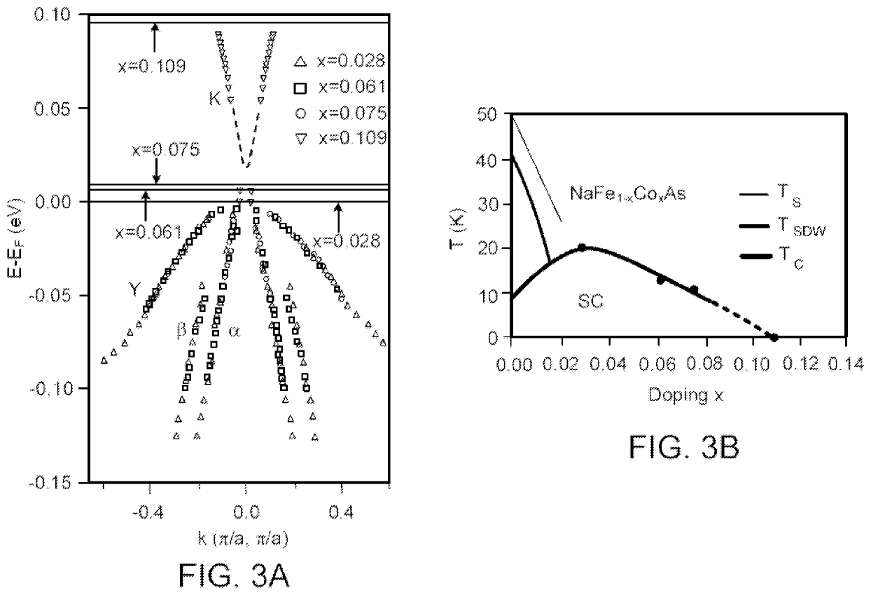

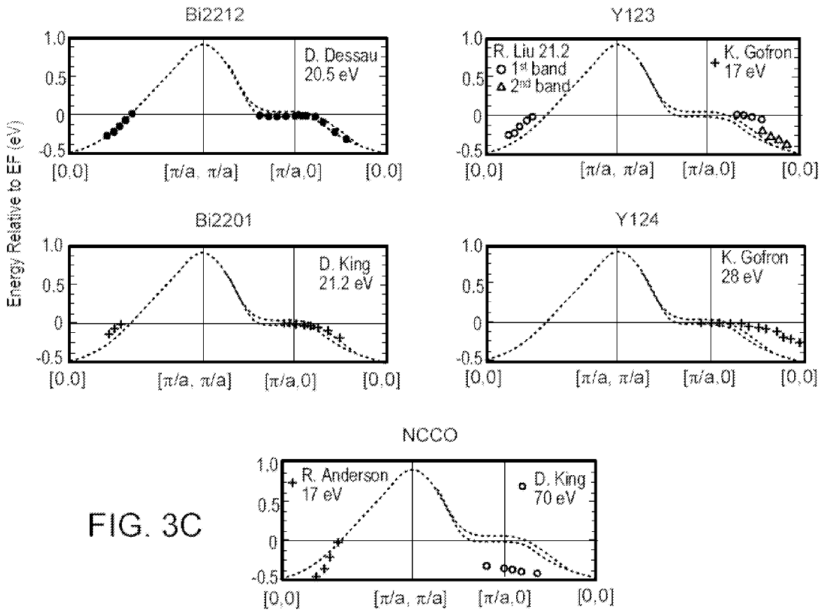

According to the above understanding, the critical temperature for superconducting effects (Tc) is believed to be determined by the size of the component ρ₂(q) and therefore by the extension in k-space of the low dispersion region ε(k). Equation (5) determines ρ₂(q) as a three dimensional sum in k-space over states that are relevant to the treatment of equations (1) to (13). These are the k states that can be described in the normal state as perturbed standing wave states. These states constitute the low dispersion region ε(k). This is consistent with measurements performed on known superconductors by ARPES showing extended low dispersion region at the proximity of the Fermi level, as can be seen in FIGS. 3A-3C, which show known measured electronic structure results.

Thus, the general principle above can identify new materials that can act as superconductors in wide range of temperature, which can be higher than the currently available superconducting materials.

Additionally, the general principle of the present disclosure provides certain superconducting materials capable of exhibiting superconductive behavior with critical temperature higher than the currently known materials. For example, certain superconducting materials described herein may provide Tc higher than 150K, higher than 200K, higher than 250K, higher than 273K, and at about room temperature (about 300K).

As shown in equation (8) and (10) above, the energy gain in the superconducting state may be determined by the third term in the right hand side of equation (8). The critical temperature is determined by that energy gain. With all other terms varying slowly among materials of the same chemical family, the energy gain depends highly on the square density term ρ₂(q) as defined in equation (5). The magnitude of ρ₂(W) is determined by the extension in k-space of the nearly flat band. As an example, FIG. 3B shows the results of angular resolved photoemission measurements on several members of the cuprate family. As seen in the figure, the nearly flat region covers about one third of the Brillouin zone. This region can be increased. Thus, according to the present disclosure, the critical temperature may be increased by replacing buffer ions within the cuprate structure (e.g., Bi2212 or YBCO) with alkali metal ions. These buffer ions control the dispersion ε(k) as can be seen below.

More specifically, the technique of the present disclosure utilizes cluster calculations for design of superconducting materials as shown in FIG. 5. In all superconductors synthesized to date with critical temperatures above the boiling point of liquid nitrogen (77K) at ambient pressure, at least one of the metal ions 11, 12, 13, and 14 in FIG. 5 is copper, anions 21, 22, 23, and 24 in FIG. 5 are all oxygen, cations 31 and 32 are alkaline earth or rare earth ions and anions 41, 42, 43, and 44 (not shown in FIG. 5 but at a location corresponding to anion 54) are all oxygen. It should be noted that the present invention includes other ionic species in the plane defined by cations 31 and anions 41, 42, and 43 and 44 and/or in the plan defined by cation 32 and anions 51, 52, 53, and 54 (in which 52 is not shown in FIG. 5 but at a location corresponding to anion 42). In some embodiments, one or more of anions 41, 42, 43, 44, 51, 52, 53, and 54 can be group VII elements (e.g., fluorine F, chlorine Cl, bromine Br, or iodine I). Without wishing to be bound by theory, it is believed that these halogen anions can stabilize the alkali metal ions 31 and 32, which can enhance the critical temperature. In some embodiments, anions 21, 22, 23, and 24 can be group VI elements (e.g., oxygen O, sulfur S, selenium Se, or tellurium Te) or group V elements (pnictogens) (e.g., nitrogen N, phosphor P, or arsenide As). It is believed that the reason to include such elements is the ability to use their p-orbitals to create a nearly bonding MO (Molecular Orbital) as explained below. It is believed that one can use these nearly bonding MOs to create the nearly flat electronic band necessary for superconductivity as explained above.

According to the present disclosure, accurate electronic state energy calculations can be performed for the octahedral structure shown in FIG. 1, which is representative of the material to be synthesized. These calculations are repeated at several representative values of the distances 34 and 35 between metal ions 31 and 32 and the plane. These values are chosen to fall in the range expected for the actual layered material, and in any case are between half the ionic radius of metal ion 31 and twice the ionic radius of metal ion 31 for distance 34, and between half the ionic radius of metal ion 32 and twice the ionic radius of metal ion 32 for distance 35. If metal ions 31 and 32 are identical, distances 34 and 35 typically are equal in each electronic state calculation. One criterion for superconductivity is that at least two of the electronic states of the octahedral structure, typically the ground state and the first excited state, are close enough in energy at some of the values of distances 34 and 35, to produce nearly flat dispersion as explained above. It should also be noted that considering the structure of the highest occupied molecular orbitals is of no less importance, as explained above.

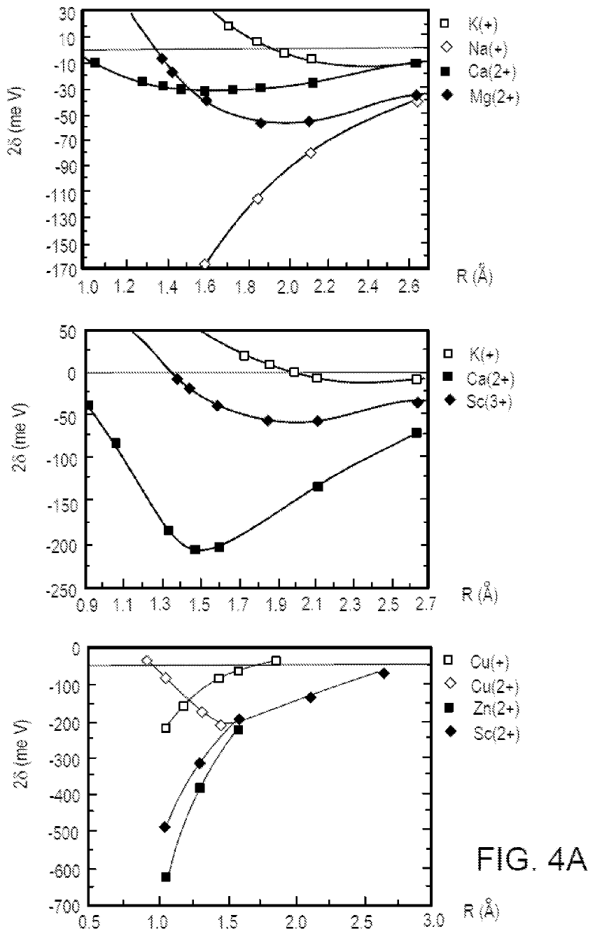

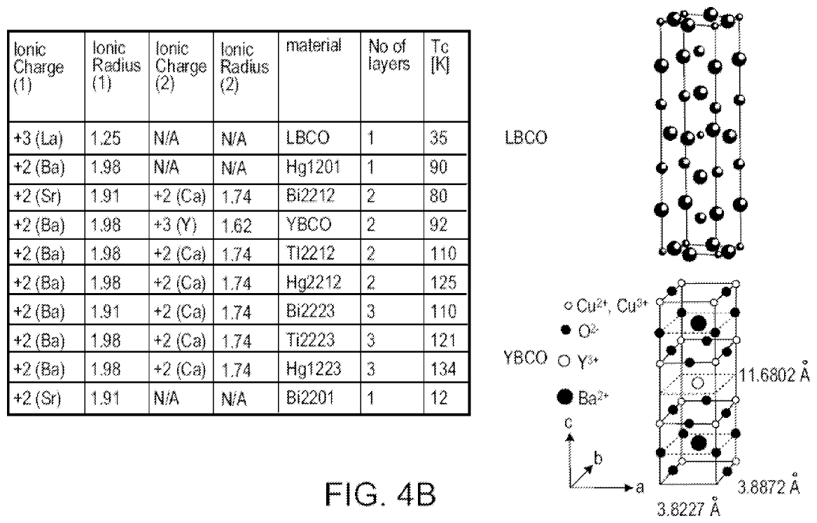

If the octahedral structure satisfies the superconductivity criterion of near degeneracy (e.g., at most 50 meV between the ground state of the cluster and the first excited state) and the proximity (e.g., at most 50 meV) between the Fermi level and the corresponding energy band, the corresponding material is to be synthesized (e.g., by using the methods described herein). Without wishing to be bound by theory, the inventor believes that the results of these calculations show several clear trends for the cuprates as seen in FIG. 4A. The data shown in FIG. 4A are collected from Panas et al., Chem. Phys. Lett, 259, 247. The most important of which is the effect of the ionic charge of the buffer ion. The lower the charge, the lower the overlap and therefore the dispersion of the narrow band. Another trend, of lower influence is the ionic radius of the buffer ion. The higher the ionic radius, the lower the overlap. The results of the quantum chemistry calculations are reproduced in FIG. 4A. These results, where pertaining to the component ρ₂(q), provide clear synthesis routes. For example, as described above, using a precursor with an excess amount of alkali metal ions and performing ion exchange proved to be efficient for inducing room temperature superconductivity. In some embodiments, oxides and nitrates can be used as precursors. In some embodiments, when using precursors containing group VI anions other than oxygen, the corresponding chalcogenides can be used. In some embodiments, an additional step of heating the sintered mixture in an oxygen atmosphere is needed to provide interstitial oxygen for hole doping. In some embodiments, when the high temperature superconductors contain mercury or thallium, they may require special treatment to be synthesized as known in the art. Superconductors can be synthesized by laser beam ablation, sputtering, molecular beam epitaxy or other methods known in the art including thin film methods. In some embodiments, artificial structures (superlattices) containing the above cluster and required charge reservoir layer or doping source can be obtained by the synthesis methods described herein.

Based on the above principle and model, the present disclosure provides the general requirements for identifying high temperature superconductors as follows: (1) the dispersion region of ε(k) at the proximity of the Fermi level is to be low (e.g., less than 50 meV), i.e. the energy differences between states in the cluster, should be as small as possible; (2) the states of this low dispersion regions should preferably be coupled to phonons (or other bosons); and (3) these electronic states should be itinerant. It should be noted that surface states or localized states can produce similar effects and appear non-dispersive in ARPES spectra while having no, or limited, contribution to superconductivity. In addition, a dispersive band, such as the Cu—O sigma band in the cuprates, supplies the screening of the coulombic potential v(q) in equation (1). [Deutscher et al., Chinese Journal of Physics, 31, 805, (1993)].

Thus, the present disclosure provides methods for identifying novel superconducting materials based on the following steps: (1) locating the frontier molecular orbitals which are almost non-bonding, which may be achieved by separating the anion atom centers by a proper distance (e.g. 3.8-4.2 Å in cuprate compounds) and the molecular orbital composed of p-orbitals which generally extend in space in the plane; and (2) locating the frontier orbitals coupled to the vibrations of a close-by metal ion approximate to the plane. At this point, the ionic charge of the metal ion approximate to the plane is preferably selected such that the energy difference between the bonding and anti-bonding levels of the frontier orbitals is minimized. It is believed that this energy difference determines the dispersion of the very narrow band. Based on appropriate cluster calculations, the ionic charge of the metal ions approximate to the plane is preferably as small as possible. For example, in cuprate compounds (i.e., copper oxides), the preferred ionic charge for the metal ions approximate to the plane is +1 or lower. In addition to the ionic charge, it is believed that the radius of the metal ion approximate to the plane in cuprate-based materials is preferably to be the high (such as the radius of K, Rb, or Cs). This can reduce the bonding-anti-bonding energy level separation. This energy level separation determines the narrow band dispersion and therefore the size of the component ρ₂(q). The size of the component ρ₂(q) determines Tc.

The table in FIG. 4B lists well known representatives of HTS materials. Column 1 lists the ionic charge of ions at the B site (i.e., the site corresponding to B in formula (I)). Column 2 lists the ionic radius of ions at the B site. Column 3 lists the ionic charge of ions at the Z site (i.e., the site corresponding to Z in formula (I)). Column 4 lists the ionic radius of ions at the Z site. Column 5 is the well-known name of the compound. Column 6 shows the number of CuO₂ layers in the compound. Column 7 lists the Tc of the different compounds. The model described above can explain qualitatively the variety of Tc in these compounds by means of the effect of the ionic charge and the ionic radius on ρ₂) as follows. The last compound is an exception to the rule, to be dealt with at the end of this paragraph. The effect of the number of CuO₂ layers is clear. Increased number of layers increases ρ₂(q) by introducing more k-states into the sum (equation 5). This works well as long as the doping mechanism is effective. Increasing the number of CuO₂ layers also increases the distance to the charge reservoir layers. The optimum is found for three layers. Therefore a good comparison will be for compounds of the same number of layers. The first two rows of the table compare the single layer compounds LBCO and Hg1201. The ionic charge at the B site decreases from +3 for LBCO to +2 for Hg1201. The value of 26, as an estimation of the oxygen band dispersion, decreases from about 130 meV (calculated for scandium) to about 40 meV (calculated for calcium). The trend is clear and, based on the model described above, Tc increases by a factor of about 3, as this is the factor of increase in ρ₂(q). The next four rows compare the double layer compounds. Going from Bi2212 to YBCO, the ion at the B position increases its radius, while the ion at the Z position increases its charge. The B position is believed to be the dominant in affecting ρ₂(q). Therefore there is a net increase in Tc. However, based on the model described herein, it is believed that a further increase in Tc will be obtained by replacing the +3 ion at the Z position (Y) with a +2 ion (Ca). This is what is shown in the next two rows displaying Tl2212 and Hg1212. The advantage of the Hg compounds over the Tl compounds is due to the linear coordination of Hg that relaxes structural strains. The three layers compounds are presented next. Bi2223 has 3 layers, but a smaller ion at the B position. Therefore the increase in Tc is significant with respect to Bi2212, but not with respect to the double layer Ba compounds, Tl2212 and Hg1212. The same goes for the 3-layer Tl compound. The increase in Tc is significant with respect to the double layer compound Tl2212, but not with respect to the strain relaxed Hg2212. The last 3-layer compound Hg2223, enjoys from all the benefits and seems to have exhausted all of the benefits of having +2 ions at the B and the Z positions. The last line shows the properties of the single layer Bi2201. The relatively low Tc of this compound can be explained by the details of its Fermi surface and the Fermi landscape.

Based on the model and principles established above, the next step would be to use +1 buffer ions with large ionic radius at the B site. The 25 value for using K+ instead of Ba++ as the buffer ion, decreases from about 40 meV to below 5 meV. Therefore, the inventor believes that such a material can have a large increase in Tc due to the large increase in ρ₂(q), even larger than the 3-fold increase in Tc, observed in 1987, by going from the +3 buffer ion at the B position to the +2 buffer ion at the B position. The inventor believes that even higher Tc by going to +1 ions at the B and Z position, with a maximum Tc for a relaxed structure containing purely +1 ions with large ionic radius, such as HgCs₂Na₂Cu₃O_{6+δ} or HgRb₂Na₂Cu₃O_{6+δ}.

Thus, without wishing to be bound by theory, the understanding of superconductivity above leads to the inventor's belief that certain materials can exhibit superconductive behavior at a relatively high temperature (e.g., at room temperature) under atmospheric pressure. For example, such materials can have a crystal structure that includes cuprate layers (i.e., copper oxide layers) having alkali metal ions located between or proximal to the layers. In some embodiments, the fraction of alkali metal ions can be higher than 0.1 (e.g., higher than 0.2, higher than 0.3, higher than 0.4, higher than 0.5, higher than 0.6, higher than 0.7, higher than 0.8, higher than 0.9, or higher than 0.95) of the total amount of metal ions adjacent to cuprate layers in the crystal structure of the superconductor compounds described herein.

Additionally, the technique of the present disclosure provides a material containing negative ions (e.g. F⁻ or O²⁻) located between at least some of the alkali metal ions and at least some of the metal oxide layers (e.g., the planes defined by anions 21-24 in FIG. 1). The negative ions provide further screening of the alkali metal ion charge and thus provide ions having effective charge below +1 (e.g., at most 0.8, at most 0.6, at most 0.5, at most 0.4, at most 0.2, at most 0.1, or 0).

In certain aspects, this disclosure features a device that is superconducting (e.g., exhibiting superconductive properties such as capable of carrying a superconducting current) at a temperature of at least 150K (e.g., at least 180K, at least 200K, at least 230 K, at least 250K, at least 273K, at least 278K, at least 283K, at least 288K, at least 293K, at least 298K, at least 300K, at least 305K, or at least 310K) under atmospheric pressure. Exemplary devices include cables, magnets, levitation devices, superconducting quantum interference devices (SQUIDs), bolometers, thin film devices, motors, generators, current limiters, superconducting magnetic energy storage (SMES) devices, quantum computers, communication devices, rapid single flux quantum devices, magnetic confinement fusion reactors, beam steering and confinement magnets (such as those used in particle accelerators), RF and microwave filters, and particle detectors.

Among other use cases noted above, the superconducting compounds described above and in the examples below can be useful in fault current limiter (FCL) devices. A FCL is a device which limits the prospective fault current when a fault occurs (e.g., in a power transmission network) without complete disconnection. Electric power distribution systems typically include circuit breakers to disconnect power in case of a fault, but to maximize reliability, it is desirable to disconnect the smallest possible portion of the network. This means that even the smallest circuit breakers, as well as all wiring to them, should be able to disconnect large fault currents.

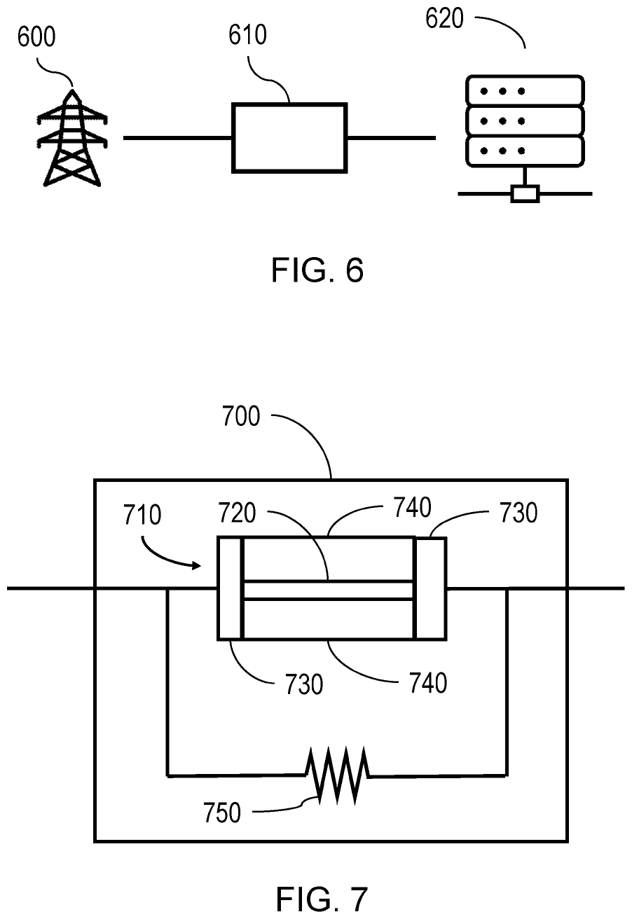

Referring to FIG. 6, the primary function of a FCL device 610 is to restrict the flow of current to a predetermined safe level, preventing excessive currents from flowing through a system, such as a power transmission network 600. By limiting the fault current, the FCL device 610 helps protect equipment, reduces stress on electrical components, such computer servers 620 drawing power from the network 600, and enhances overall system stability.

The FCL device 610 is a nonlinear element which has a low impedance at normal current levels, but presents a higher impedance at fault current levels. Further, this change is extremely rapid, before a circuit breaker can trip a few milliseconds later. While the power is unstable during the fault, it is not completely disconnected from the network. Once the current returns to normal levels, such as after a faulting branch of a power distribution network is disconnected, the fault current limiter automatically returns to normal operation.

Superconducting fault current limiters exploit the extremely rapid loss of superconductivity (“quenching”) above a critical temperature, critical current density, and/or a critical magnetic field strength. In normal operation, current flows through the superconductor with zero or near zero resistance and negligible impedance. If a fault develops, the superconductor quenches, its resistance rises sharply, and current is diverted to a parallel circuit with the desired higher impedance.

In general, superconducting FCL devices include resistive devices and inductive devices. Generally, the choice of fault current limiter depends on various factors, including the specific application, system requirements, and budget constraints. FCLs play a crucial role in maintaining the reliability and safety of electrical power systems by mitigating the impact of fault currents and preventing damage to equipment and infrastructure.

Referring to FIG. 7, an example of a resistive FCL device 700 includes a superconducting electrically conductive element 710 that is connected in parallel with a resistor 750. The element 710 includes a superconducting line 720 extending between two electrical contacts 730. A heat sink 740 is arranged in thermal contact with the superconducting line 720. The heat sink is formed from a material that has sufficient thermal conductivity to rapidly conduct heat away from the superconducting line 720.

The element 710 is designed to provide sufficient superconducting current capacity so that during normal operation of the device 700, the current passes directly through the element 710 in a superconducting state. However, the element 210 has a current threshold above which it quenches. When it quenches, e.g., due to a fault current, the sharp rise in resistance reduces the fault current from what it would otherwise be (the prospective fault current). The device 700 can be designed according to a desired current threshold depending on the application for which the device is to be used.

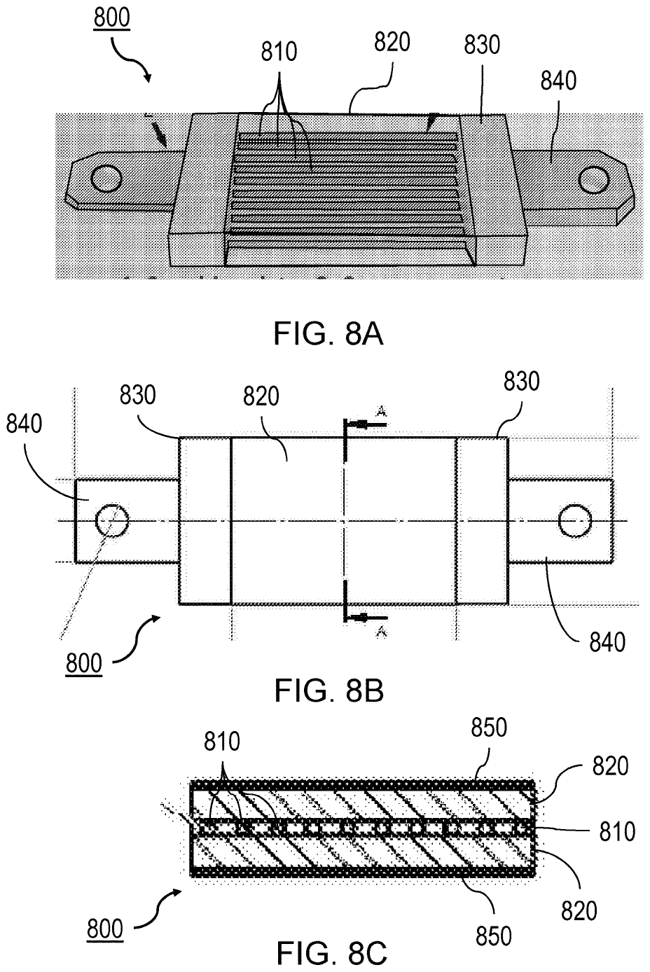

An example of a resistive FCL element 800 is shown in FIGS. 8A-8C. Element 800 includes multiple strips 810 of superconducting material extending between two electrical contacts 830. The strips 810 are separated by an electrically insulating material and each provide a parallel superconducting electrical connection between contacts 830 under normal operating conditions (below Tc and below the critical current of the superconducting strips). Contacts 830 are each integrated with electrical contact pads 840 for bolting the element 800 to electrical transmission lines or other components of the electrical circuit. The contacts 830 and pads 840 are formed from an electrically conducting material, such as copper.

Strips 810 are arranged between two sapphire plates 820, which act as a heat sink for the element. The material between the strips can also be sapphire. Additional outer layers 850 can also be included. In some cases, these layers can be an electrically conducting material, such as copper. In certain examples, these layers can operate as ohmic conductors that carry current when the fault current threshold is exceeded. In some examples, these layers can be protective layers.

Generally, the dimensions of the device, number of superconducting strips, and other parameters can be selected based on the use case for the FCL. Multiple such elements can be stacked together and connected in parallel to provide greater capacity than a single element.

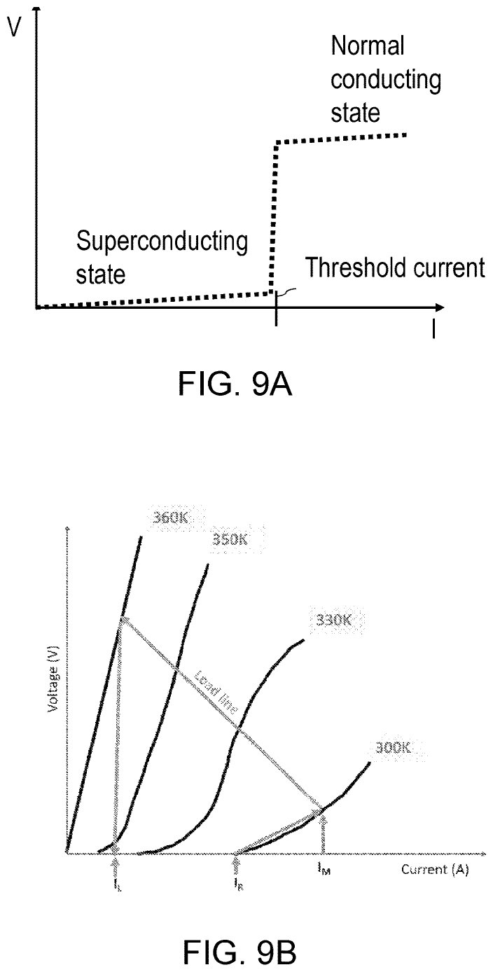

A threshold current for a superconducting compound useful for such FCL devices can be established based on the current-voltage characteristics of the material or device. An example current-voltage curve for a superconducting material is shown in FIG. 9A. Examples of such curves for specific compound samples are discussed further below, in the Examples. The current-voltage curve, which is acquired for a fixed temperature below Tc, shows a sharp transition from a superconducting state to a normal conducting state at a threshold current. This transition is indicative of a significant jump in resistance in the sample under test.

The threshold current and the steepness of the I-V curve during the transition can depend on the device and its operating temperature. FIG. 9B, for example, depicts I-V curves for an example device at four different temperatures spanning Tc, adapted from Prof A. Campbell, University of Cambridge. At 300K, the lowest operating temperature depicted in this plot and below Tc, the transition begins at a current IR >0 Amps, and increases monotonically with increasing current. At 330K, the transition begins a lower current and follows an S-shaped transition, with a steeper increase that the 300K curve, where similar current values to the 300K curve are achieved at significantly higher voltages (indicating increased resistance). At 350K, a temperature still below Tc, a transition from superconducting to normal is still evident, although the threshold current is lower than the threshold current for 330K. Device resistance at this temperature is still higher than at 330K for the same current. Finally, the I-V curve at 360K is linear and corresponds to an ohmic conductor, indicating that the device is no longer superconducting.

In a resistive FCL device, even with a heat sink, the onset of the transition from superconducting to normal can result in significant and rapid heating of the superconductor, which in turn increases the resistance of the sample. Such behavior can be advantageous in a FCL, where a rapid increase in impedance in the circuit is desired to prevent exposure of equipment to the fault current.

Generally, a resistive FCL device can be either DC or AC. If it is AC, then there can be a steady power dissipation from AC losses (superconducting hysteresis losses) which are removed by the heat sink 240.

Referring to FIG. 10, an inductive FCL device 1000 is generally designed as a transformer with a resistive FCL as the secondary coil 1010 (e.g., having an iron core). The secondary coil 1010 is inductively coupled to a primary coil 1010, which is series connected into the transmission line. In un-faulted operation, there is little or no resistance in the secondary coil 1010 and so the inductance of the device is low. A fault current in the primary coil induces a current in the secondary coil that quenches the superconductor, so the secondary coil 1010 becomes resistive and the inductance of the whole device rises. An advantage of this design is that there is no heat ingress through current leads into the superconductor, and so any cryogenic power load may be lower.

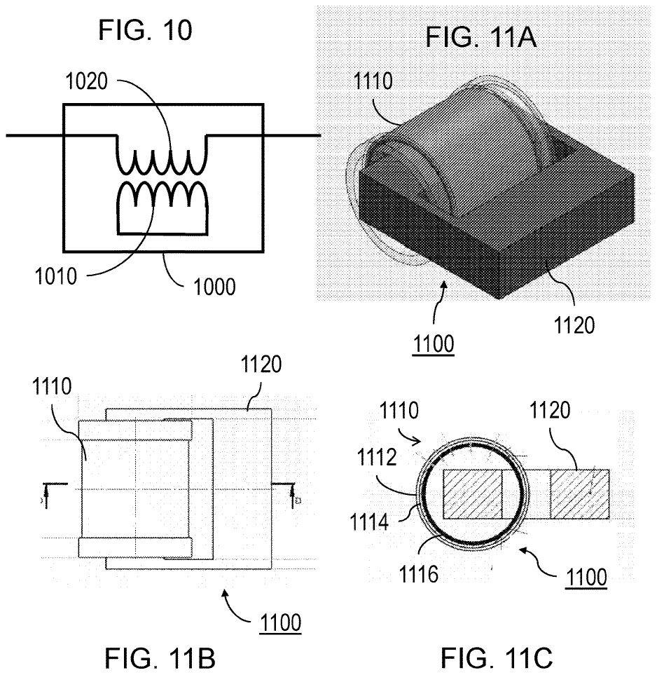

An example of a superconducting secondary coil 1100 for an inductive FCL device is shown in FIGS. 11A-11C. Secondary coil 1100 includes a wound coil 1110 and an iron core 1120 (or other ferromagnetic material). The coil 1110 includes bulk cylinder of a superconducting wire 1116 within a sapphire cylinder 1114. An outer coil of copper wire 1112 is wound around the sapphire cylinder 1114. In this example, the core 1120 is a closed core. In other examples, the core can be an open core.

While the foregoing example FCLs operation at room temperature and don't include a cryogen to maintain the superconducting state, other implementations are possible. For example, any of the above examples can optionally include a cooling system to maintain the temperature of the superconducting element below a threshold temperature. The cooling system can include a coolant, such as water, oil, or a cryogen, such as liquid nitrogen.

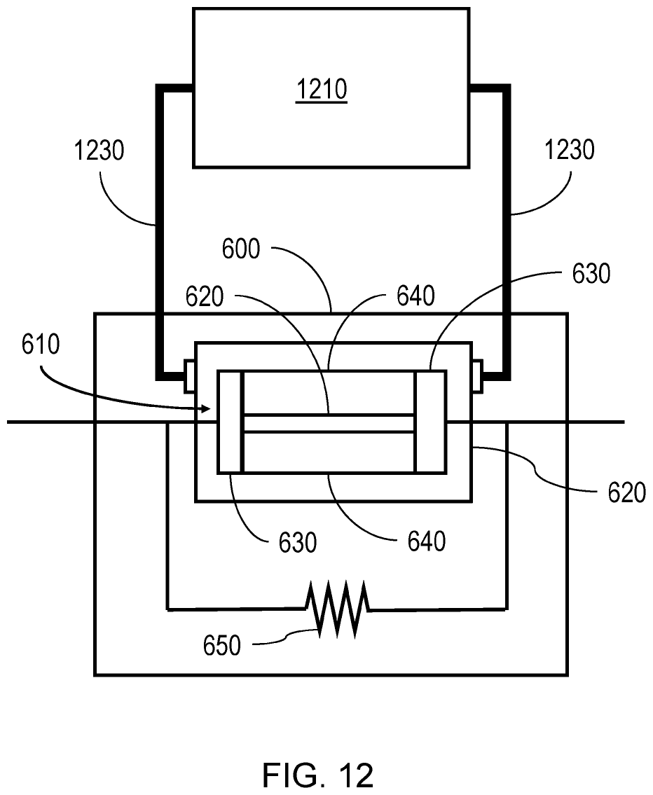

Referring to FIG. 12, an example FCL system 1200 includes a cooling system is shown. Here, the system 1200 includes FCL device 700 described above connected to a cooling subsystem 1210. The system 1200 includes a cryostat 1220 which houses superconducting element 710. The cooling subsystem 1210 is connected to the cryostat 1220 via conduits 1230 which guide a coolant from the subsystem 1210 to the cryostat. The coolant maintains the temperature of the superconducting material in the element 710 below the critical temperature of the superconducting material so that, under normal current conductions, the element 710 carries current. In some examples, the cooling system 1210 can variably control the temperature of the superconducting material to vary the threshold current of the FCL device 700.

In each of the example superconducting FCLs described above, the superconducting material can include one or more of the superconducting materials described above and in the examples below. In general, the critical temperature for the superconducting FCL device can be 200 K or more (e.g., 250K or more, 300 K or more, 350K or more). The critical current for the superconducting FCL device can vary depending on the application, and can range from 1 amp (A) to 100 kA (e.g., in a range from 10 A to 100 A, from 100 A to 1 kA, from 1 Ka to 100 kA). An advantage of the FCL devices described herein is the ability to tune the device to an appropriate critical current according to the specific use case for the FCL device. Thus, for example, a high voltage network that operates at high voltage and low current can utilize an FCL device having a first critical current, while other applications such as a data center operates at low voltage (e.g., 400 V) and high current (e.g., 20 kA) can utilize a different FCL device with a different (e.g., higher) critical current.

The contents of all publications cited herein (e.g., patents, patent application publications, and articles) are hereby incorporated by reference in their entirety.

### General Description of Synthesis and Characterization of High Temperature Superconductors

As mentioned herein, the chemical compositions of the compounds described in the Examples were measured by using Energy Dispersive Spectroscopy (EDS). The Tc of the compounds described in the Examples were measured by using the four probe method [Low Level Measurements Handbook, 6th edition, Keithley]. The transport measurements were obtained using a Quantum Design PPMS system located at University of Zaragoza (UNIZAR), or using Keithley 2450 source measurement unit (SMU) and Keithley 2430 SMU. The magnetic measurements were done using Quantum Design MPMS system, located at UNIZAR or at Weizmann Institute of Science (WIS)

The following family of compounds derived from the model outlined above were synthesized and exhibited room temperature superconductivity properties: YBCO and BSCCO modified to contain an alkali metal ion (e.g., K or Rb) and a halogen anion (e.g., F).

A variety of compounds belonging to the family above were synthesized by the following general procedure: For YBCO, stoichiometric amounts of CuO, BaCO₃, KF or RbF, and Y₂O₃ were ground, pressed, and sintered at 700-850° C. for 24-72 hours to prepare Y(KₓBa₁₋ₓ)ᵣCuₚO_{y}Fₛ or Y(RbₓBa₁₋ₓ)ᵣCuₚO_{y}Fₛ, in which x is from 0.2 to 1, r is 1 to 5, p is from 1 to 4, y is from 3 to 7, and s is from 0.3 to 4. For BSCCO, stoichiometric amounts of CuO, Bi₂O₃, RbF, SrCO₃ and CaCO₃ were ground, pressed, and sintered at 690-820° C. for 24-96 hours to prepare Biₙ(RbₓSr₁₋ₓ)ᵣCaₚ₋₁CuₚO_{y}Fₛ, in which n is from 2-4, x is from 0.2 to 1, r is 1 to 3, p is from 0 to 3, y is from 6 to 18, and s is from 0.3 to 2.

Further, in some of the cases, the reaction was done in 1-5 stages of grinding, pressing and sintering. The mixtures in most cases were grinded in a glove box filled with an inert atmosphere such as Ar or N₂, pressed in the glove box and then sintered in an inert atmosphere at 690-810° C. Variations with respect to this generic procedure are detailed in the examples. In some implementations, the sintering temperature is between 680° C. and 750° C. The sintering temperature ranges described here may, in some cases, provide a useful balance between temperatures that are not too high (e.g., resulting in melting or undesirable compound formation) and not too low (e.g., to provide high-purity compositions).

Moreover, in some cases, these temperature ranges are lower than temperatures typically used to process YBCO/BSCCO compounds, because of the presence of the alkali metals in the modified compounds can suppress the melting temperature. For example, in some implementations, the sintering temperature is 900° C. or less, 875° C. or less, or 850° C. or less, temperature ranges that may reduce (e.g., inhibit) melting.

Processing in an inert atmosphere has been recognized, for purposes of this disclosure, as useful for synthesis of the described compounds including a halogen such as F. Halogens may react strongly with water vapor in the atmosphere, interfering with synthesis of these compounds. Accordingly, the inert atmosphere can promote high-purity synthesis of these compounds, resulting in more uniform morphology and/or higher superconducting critical temperature.

In some implementations, after at least one sintering cycle, the sintered composition is heated in an oxygen atmosphere to provide interstitial and/or structural oxygen for hole doping. The doping can increase conductivity and/or Tc.

In some implementations, the sintered composition is purified in a micro pulling down crystal growth (μ-PD) process. In a μ-PD process, the sintered composition (e.g., any of Compounds 1-7 described below) is melted in a crucible and transported through a micro-channel/capillary made in the crucible bottom. Continuous solidification of the melt is progressed on a liquid/solid interface positioned under the crucible, resulting in formation of a high-purity crystal. Because of the inclusion of halogens in the compounds discussed herein, this process is performed in an inert atmosphere.

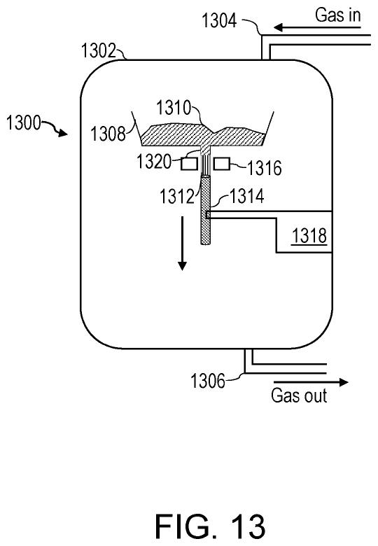

For example, as shown in FIG. 13, a μ-PD apparatus 1300 includes a sealed chamber 1302, for example, a stainless steel and/or glass chamber. To facilitate maintenance of an inert atmosphere in the chamber 1302, the μ-PD apparatus 1300 includes a gas inlet 1304 (e.g., for inflow of nitrogen and/or argon) and a gas outlet 1306 (e.g., fluidically connected to a pump).

A heated crucible 1308 is inside the chamber 1302 to hold the sintered composition 1310. The crucible 1308 can be, for example, a platinum crucible or a crucible or another material that can withstand temperatures used to melt the sintered composition 1310. The sintered composition 1310 is melted (e.g., at temperatures that range from 800° C. to 1,000° C., depending on the composition) and flows through a micro-nozzle 1320. The flow of the melted sintered composition meets a seed crystal 1314, and a grown crystal 1312 is formed based on the crystal structure of the seed crystal 1314. For example, a meniscus of the melted sintered composition can be formed at an orifice of the micro-nozzle 1320, and the seed crystal 1314 can initially be positioned to meet the meniscus and form a liquid/solid interface at the bottom of the orifice. The seed crystal 1314 can be an oriented bar cut from a previous growth of the same or a similar composition, a crystal of the same or a similar composition obtained by μ-PD or otherwise, or a different isostructural crystal having a higher melting point than the melted sintered composition. In some implementations, an after-heater 1316 (e.g., heating coil(s), such as platinum wires) is arranged adjacent to the flow of the melted sintered composition and controlled to provide an adjustable temperature gradient along the growth direction and/or in an axial direction. In some implementations, the longitudinal temperature gradient along the growth direction is between 10° C./mm and 100° C./mm. In some implementations, the axial temperature gradient is between 100° C./mm and 300° C./mm. These temperatures have been observed to provide high-purity crystal fibers with few or new crystal defects.

During crystal growth, the seed crystal 1314 is moved downward inside the chamber a02 with respect to the crucible 1308/melt of the sintered composition 1310, e.g., using a control arm, actuator, moving platform, elevator, or other movement mechanism 1318 configured to move the seed crystal 1314 downward. In some implementations, the movement speed is between 0.2 mm/min and 2.0 mm/min, speeds that have been observed to provide high-quality crystals. Accordingly, the grown crystal 1312 gradually increases in length. After crystal growth to a desired length, the grown crystal 1312 is allowed to cool, e.g., to room temperature.

A length of the solute diffusion boundary layer can be controlled by adjusting the length of the micro-nozzle 1320, where there is little or no convection. In some implementations, the length of the diffusion layer in stable growth is set to be about 100 μm. In addition, the crystal growth velocity can be 10²-10³ times higher than that in a conventional melt growth method. As a result, more compositionally homogenous crystals of the superconducting compounds described herein are grown compared to results provided by some alternative crystal growth methods, e.g., having a segregation coefficient Keff ~1.

Voids, dislocations were not appearing in such method grown fiber crystals. The very stable and linear radial temperature distribution in a growth region is assumed to depress dislocation generation.

The use of apparatuses such as apparatus 1300, with seed crystal movement and crystal growth occurring in an inert atmosphere in a sealed chamber, can permit the inclusion of alkali and halogen ions in the crystals.

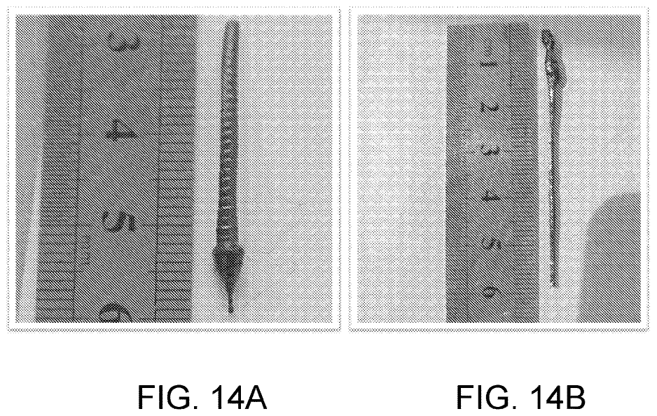

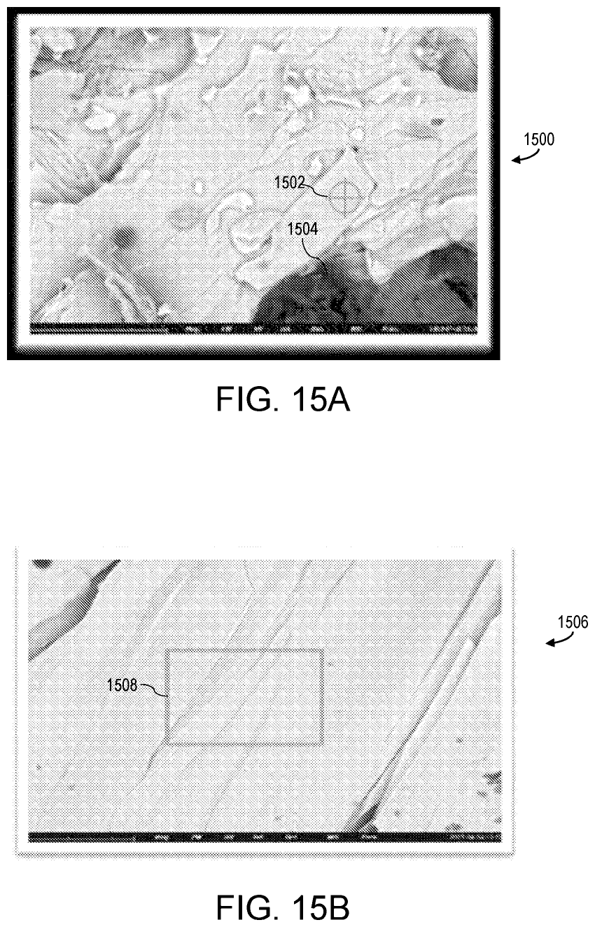

In some implementations, the crystals are grown as fibers. Fibers grown according to the foregoing methods have been observed to be crack-free with uniform diameters; to be composed of plate-like crystals; and to exhibit superconductivity, e.g., at high temperatures. For example, FIGS. 14A-14B illustrate examples of fibers with lengths of approximately 3 cm and approximately 6 cm, respectively. The fibers were grown by sintering a mixture to obtain BSCCO and melting and re-crystallizing the BSCCO using μ-PD as shown in FIG. 13. The fibers have generally uniform morphology along their length, reflecting their homogenous composition. This homogeneity is further shown in FIGS. 15A-15B, where FIG. 15A is an SEM micrograph of a sintered BSCCO compound 1500 prior to melting and recrystallization using μ-PD, and FIG. 15B is an SEM micrograph of the post-μ-PD BSCCO compound 1506. Compound 1500 is highly heterogeneous on the illustrated microscopic level. For example, at location 1502, compound 1500 has O %=41, Ca %=9, Cu %=13, Sr %=11, and Bi %=26, while location 1504 is CuO. Sintered BSCCO compounds were found to have about 50% purity (50% composition of Bi2212 or Bi2201). By contrast, BSCCO compounds synthesized additionally using μ-PD were found to have over 90% purity, with area 1508 of compound 1506 having composition O %=49, Ca %=6, Cu %=12, Sr %=14, and Bi %=19.

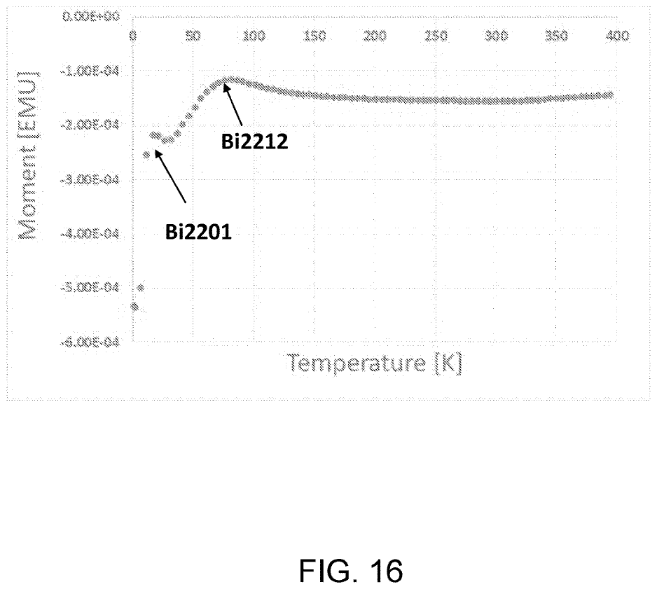

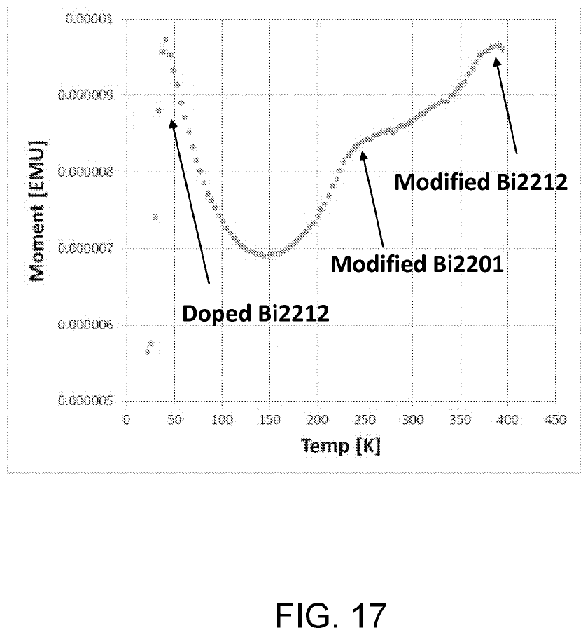

Magnetic measurements have shown that the μ-PD-processed compounds have an intergrowth of Bi2201 and Bi2212. For example, as shown in FIG. 16 (illustrating sample magnetic moment as a function of temperature using a SQUID magnetometer), two labeled peaks/transitions indicate the presence of Bi2201 and Bi2212 in the same sample, with Bi2201 making up the majority of the sample. This effect has been observed both in compositions that include a halogen anion and an alkali metal ion, and in samples that do not. For example, as shown in FIG. 17, with measurements taken under conditions of H=100 Oe, a sintered BCBO composition modified with Rb and F inclusions exhibited two labeled peaks corresponding to Bi2201 and Bi2212 portions, along with a low-T transition associated with doped Bi2212.

For purposes of this disclosure, it has been recognized that the proportion of Bi2212 in the synthesized materials can be a target parameter to be adjusted to improve material performance. For example, in some cases, Bi2212 is associated with a higher superconducting transition temperature than other phases (e.g., Bi2201), such that increasing the Bi2212% can provide higher critical current and/or critical magnetic field at high temperature. In some implementations, one or more processing temperatures for the composition—sintering temperature, recrystallization temperature, or both—can at least partially determine Bi2212%, and it has been observed that this effect is sensitive, with small differences in temperature (e.g., less than 20° C.) resulting in large changes in Bi2212% in sintered compositions and fibers obtained from μ-PD. For example, in some implementations, Bi2212% is at least 50%, at least 75%, or at least 90%.

The use of μ-PD is not limited to the particular example of Bi2212 compounds. Rather, other types of superconducting compounds within the scope of this disclosure, such as YBCO, Bi2223, Tl2212, Tl2223, Hg1201, Hg1212, and Hg1223, can also be processed using μ-PD to obtain some or all of the benefits described with respect to Bi2212. For example, a purity of fibers formed by these processes (e.g., a volume % of modified YBCO, modified Bi2223, etc.) in the fibers can be at least 90%.

The following examples are illustrative and not intended to be limiting.

### EXAMPLES

### Example 1: Synthesis and Characterization of Superconducting Compounds 1-3

Bi₂O₃, CuO, RbF, SrCO₃, and CaCO₃ were weighed according to three nominal compositions: Bi₂Rb_{1.2}Sr_{0.8}CaCu₂OₓF_{1.4} (Compound 1 or B2B60), Bi₂Rb_{1.4}Sr_{0.6}CaCu₂OₓF_{1.4} (Compound 2 or B2B70) and Bi₂Rb_{0.8}Sr_{0.6}Ca_{0.6}CuOₓF_{1.4} (Compound 3 or B1BC40). The powder was pelletized at a pressure of 4000 kg/cm² at room temperature and grinded in a ball mill machine at 750 RPM for 5 hours. Round shaped pellets (with an average diameter of 7 mm) were used for the following sintering cycles procedure. For the final electrical measurements, square shaped pellets (8 mm) were pressed and sintered. This procedure took place inside a glove box filled with inert atmosphere of nitrogen.

Sintering procedure was performed at 710° C. for B2B70 and B2B60 and 690° C. for B1BC40 in a furnace. Each cycle of thermal treatment included heating a sample from 200° C. to the target temperature at a heating rate of 5° C./minute and holding the sample at the target temperature for a total of 12 hours. At the end of each thermal treatment, samples were cooled to 200° C. inside the furnace. The cooling took several hours without control of the cooling rate. The above sintering cycle was performed for a predetermined number of times (e.g., three or four times) for each sample. After the sintering cycle, each batch of pellets was reground and pelletized inside the glove box.

The samples were investigated by SEM observation, EDS analysis and x-ray powder diffraction (XRPD). SEM Micrographs and EDS analysis were carried out on Phenom ProX G6 Desktop SEM by Thermo Fisher. Phase analysis of the sample was performed by XRPD method. The data were collected on a Panalytical Empyrean powder diffractometer (Kα radiation, λ=1.541 Å) equipped with an X'Celerator linear detector and operated at v=40 kV, I=30 mA. All measurements described herein were performed under ambient pressure.

Electrical measurements were performed by a standard continuous DC four probe method using an interactive digital source meters Keithley 2450 SMU and Keithley 2430 SMU.

Several configurations were developed for assembling the contacts for the electrical measurements as described below:
(1) Four indium contacts points were gently pressed on top of a pellet. Solid core Cu wires were attached to the indium contact by silver paste. Dielectric coating was applied, covering the entire sample and base, and was left to dry on the hot plate at 120° C. for 20 minutes. The coating procedure was repeated twice to ensure sealing of the sample to air.
(2) Four indium contacts were pressed on top of a 10 mm silicon wafer. Cu wires were attached to the indium contacts using silver epoxy. Rectangular pellet was attached to the indium contacts using drops of silver epoxy. The procedure took place on a hot plate at 130° C., then the device was left for hardening for 1 hour. Dielectric coating was applied in a manner similarly to the previous configuration. In order to seal the device completely and ensure inert atmosphere, the device was sealed inside of a designated package. Sealing was performed using arc welding procedure inside a glove box.
(3) To improve the contact of the indium with the sample, a new configuration using printed circuit board (PCB) was developed. In this method, PCB was designed with gold mask on top of it, designated for the indium contacts. After indium wires were soldered on top of gold mask, Cu wires were soldered in the designated positions. The pellet was then placed on top of the contacts and pressed by a second, similar, PCB using 4 screws. Dielectric coating was applied similarly to the previous configurations except that a longer suspension on the heating plate was needed due to the geometry of the device (3 hours, 120° C.). Hermetic sealing packages were used due to the geometry of the new PCB device. All compounds were measured by this configuration.
(4) In some implementations, contacts are formed by high-temperature diffusion of silver into the synthesized compositions. This can result in fabrication of Ohmic contacts as opposed to blocking Schottky contacts.

### Results

Superconducting Compound 1 (B2B60) was prepared following the procedure described above. The composition of Compound 1 was measured by EDS at four spots on a sample and the results are summarized in Table 1 below. As used herein, the unit “at %” refers to atomic percentage. As shown in Table 1, the atomic fractions suggest that Compound 1 has the following formula: Bi₂(Sr,Rb,Ca)₂CuO_{y}Fₛ.

TABLE 1

| Spot | Bi at % | Sr at % | Rb at % | Ca at % | Cu at % | O at % | F at % |
|---|---|---|---|---|---|---|---|
| 1 | 22.16 | 7.25 | 4.46 | 8.40 | 11.76 | 44.82 | 1.18 |
| 2 | 21.26 | 5.90 | 10.59 | 7.60 | 11.86 | 40.42 | 2.40 |
| 3 | 23.64 | 8.52 | 0.20 | 7.71 | 12.10 | 46.66 | 1.19 |
| 4 | 22.60 | 8.53 | 1.40 | 7.57 | 11.65 | 42.19 | 1.17 |

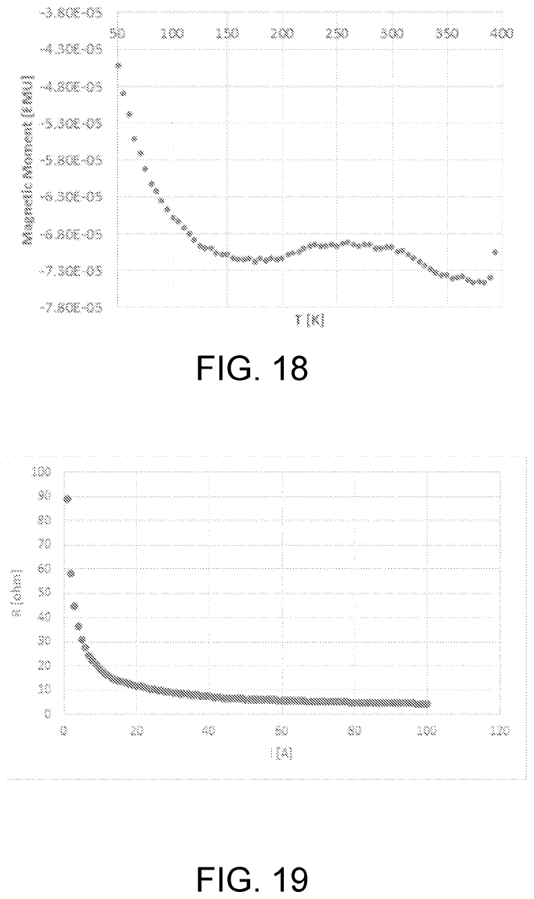

The magnetic measurements of Compound 1 were performed and the results are shown in FIG. 18. Based on FIG. 18, it is estimated that the critical temperature (Tc) of Compound 1 is above 400K.

FIG. 19 shows the resistance as function of current of the pristine Bi2212 material obtained by using four probe electrical measurements. The resistance saturates at about 4.5 ohm at 20° C. under ambient pressure.

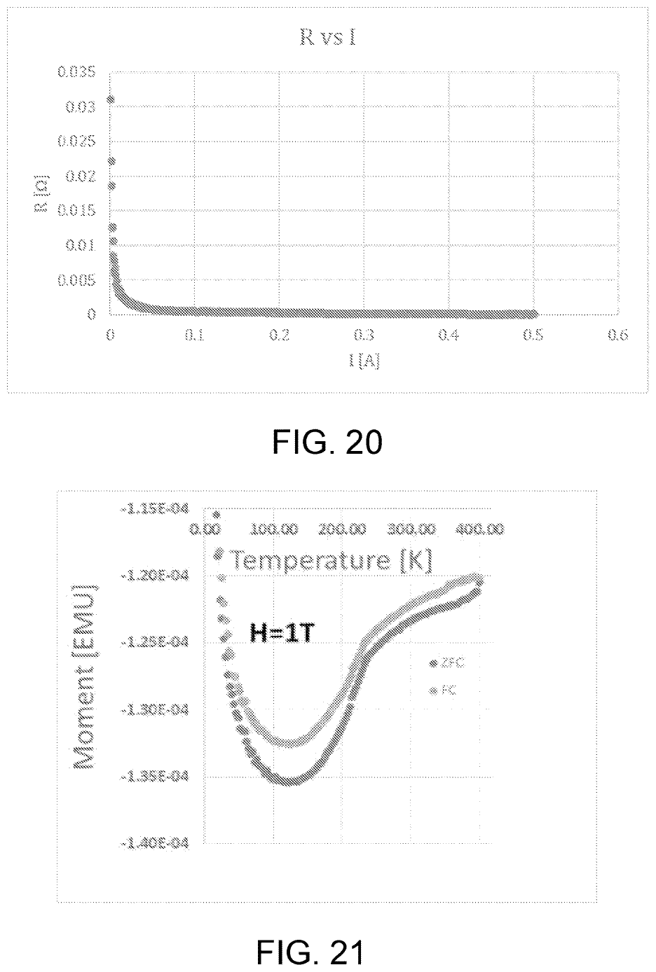

FIG. 20 shows the same four probe electrical measurement under the same conditions and the same form factor for B2B60 (i.e., Compound 1) obtained above by using the second configuration. As shown in FIG. 20, the resistance saturated at about 10\hat{ }−5 ohms at 293K under ambient pressure. Based on the negligible resistance shown in FIG. 20, it is estimated that critical temperature of B2B60 is above 293K. Without wishing to be bound by theory, it is believed that the relatively high resistance at the low current was caused by imperfect electric contacts.

The magnetic measurements of Compound 1 were performed and the results are shown in FIG. 21. As shown in FIG. 21, when measured at IT magnetic field strength, Compound 1 exhibited hysteresis effects in its magnetic measurements between the Zero Field Cooled (ZFC) measurement (i.e., the lower curve) and the Field Cooled (FC) measurement (i.e., the upper curve), consistent with the behavior of a superconducting compound.

Superconducting Compound 2 (B2B70) was prepared following the procedure described above. The composition of Compound 2 was measured by EDS at three spots on a sample and the results are summarized in Table 2 below. As shown in Table 2, the atomic fractions suggest that Compound 2 has the following formula:

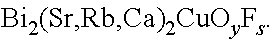

TABLE 2

| Spot | Bi at % | Sr at % | Rb at % | Ca at % | Cu at % | O at % | F at % |
|---|---|---|---|---|---|---|---|
| 1 | 20.29 | 6.05 | 3.62 | 7.21 | 10.83 | 51.68 | 0.36 |
| 2 | 15.63 | 5.29 | 4.07 | 5.92 | 7.93 | 61.17 | 0.00 |
| 3 | 17.28 | 6.09 | 1.14 | 6.35 | 9.73 | 59.09 | 0.32 |

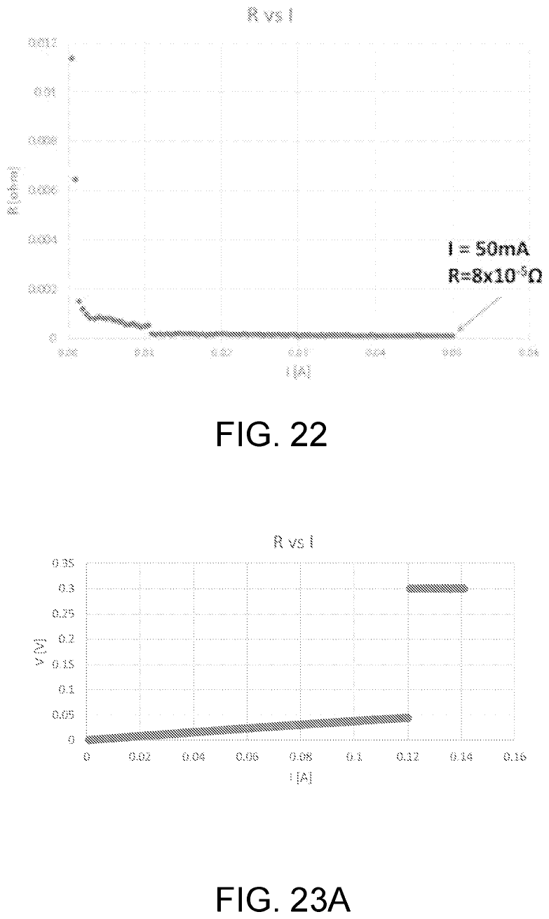

FIG. 22 shows the same four probe electrical measurement under the same conditions and the same form factor for B2B70 (i.e., Compound 2). As shown in FIG. 22, the resistance saturated at about 8*10\hat{ }−5 ohms at 293K under ambient pressure. Based on the negligible resistance shown in FIG. 22, it is estimated that critical temperature of B2B70 is above 293K.

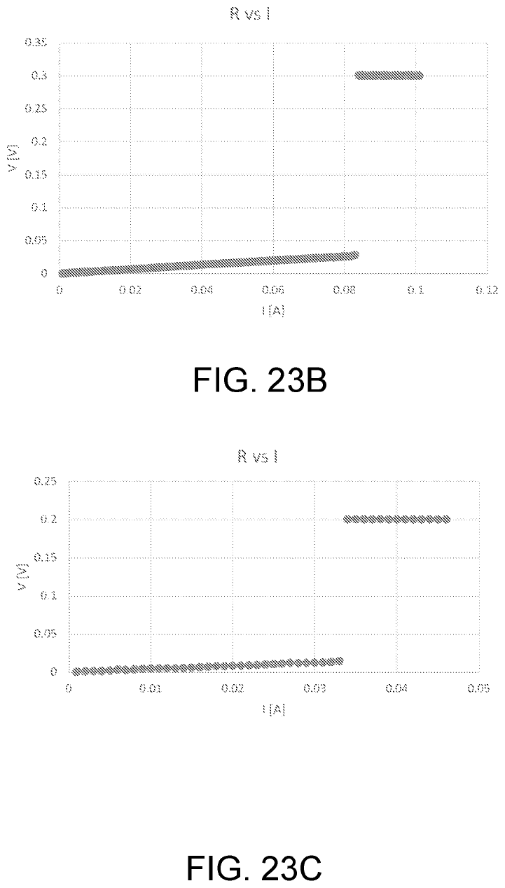

FIG. 23A-C show the four probe electrical measurement under the same conditions and the same form factor for B2B70 except that the sample shown in FIG. 23A was obtained by performing the sintering cycle six times, the sample shown in FIG. 23B was obtained by performing the sintering cycle four times, and the sample shown in FIG. 23C was obtained by performing the sintering cycle five times. For the samples shown in FIGS. 23A-B, the contacts were made by using the first configuration described above. For the sample shown in FIG. 23C, the contacts were made by using the second configuration described above. As shown in FIGS. 23A-C, B2B70 exhibited a sharp jump in the voltage at the critical current, which can be exploited for use in FCL devices as described previously.

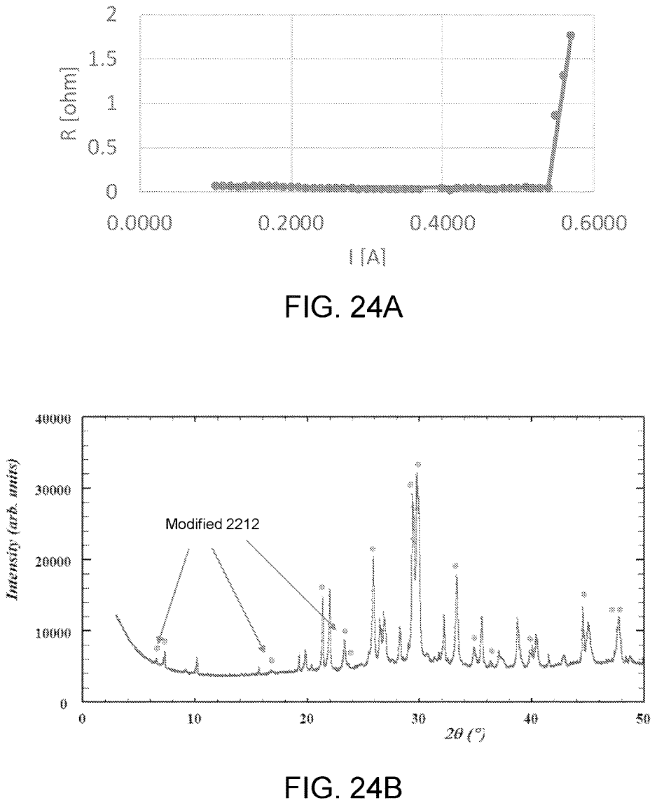

The measured resistance as a function of current for a sample of B2B70 (i.e., compound 2) is shown in FIG. 24A. This measurement was performed at a temperature of 75° C. The resistance remains negligible for currents up to about 0.55 A, after resistance of the sample rapidly increases. This behavior is characteristic of a superconducting material for currents below and at the critical current for the sample.

XRD analysis of Compound 2 was performed and the results are shown in FIG. 24. Rietveld analysis converged with Ri=3.5%. In FIG. 24B, the peaks from modified Bi2212 are identified and the remaining peaks marked by circles are from modified Bi2201. As shown in FIG. 24B, the majority structures obtained were modified Bi2201, while a small amount of modified Bi2212 was identified. It is believed that the small fraction (about 3.5%) of modified Bi2212 is responsible for the observed room temperature superconductivity. The majority phase (50%) of modified Bi2201 is believed to be a superconductor with lower Tc. It is believed that the synthesis temperature is the determining factor in increasing the fraction of modified Bi2212 at the expense of modified Bi2201.

Superconducting Compound 3 (B1BC40) was prepared following the procedure described above. The composition of Compound 3 was measured by EDS at two spots on a sample and the results are summarized in Table 3 below. As shown in Table 3, the atomic fractions suggest that Compound 3 has the following formula:

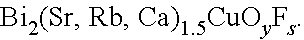

TABLE 3

| Spot | Bi at % | Sr at % | Rb at % | Ca at % | Cu at % | O at % | F at % |
|---|---|---|---|---|---|---|---|
| 1 | 26.62 | 8.73 | 1.63 | 5.54 | 12.95 | 1.3 | 43.21 |
| 2 | 24.16 | 6.97 | 3.39 | 5.33 | 10.82 | 2.01 | 47.28 |

### Example 2: Characterization of Superconducting Compound 4

Superconducting Compound 4 was prepared following the procedure described above except that the sintering lasted 48 hours at 750° C. The composition of Compound 4 was measured by EDS and the results are summarized in Table 4 below. As shown in Table 4, the atomic fractions suggest that Compound 4 has the following formula:

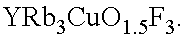

TABLE 4

| Y at % | Rb at % | Cu at % | O at % | F at % |
|---|---|---|---|---|
| 9.86 | 32.72 | 10.89 | 14 | 32.5 |

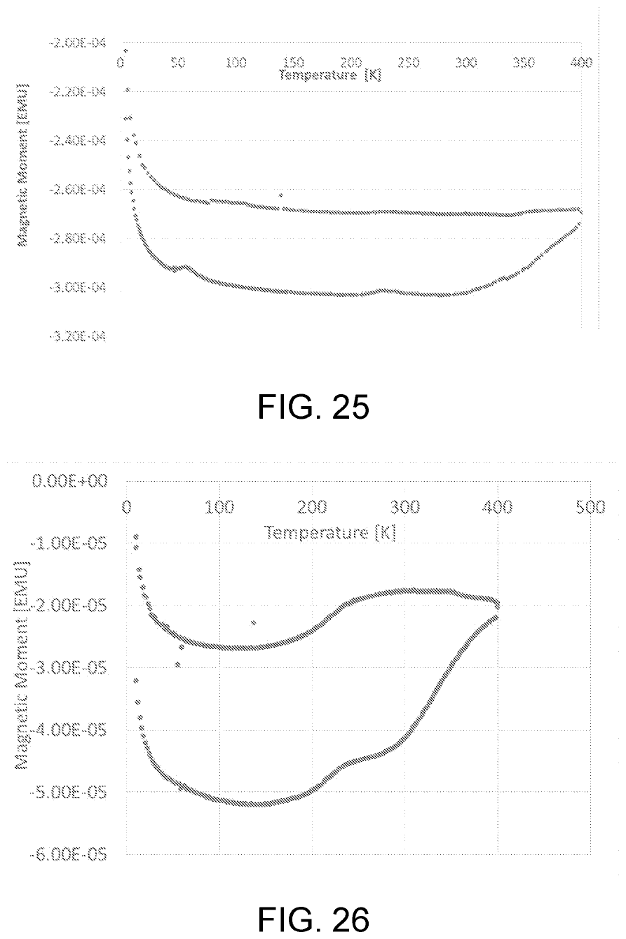

The magnetic measurements of Compound 4 was performed and the results are shown in FIG. 25. As shown in FIG. 25, when measured at 1 T Compound 4 exhibited hysteresis effects in its magnetic measurements between the Zero Field Cooled (ZFC) measurement (i.e., the lower curve) and the Field Cooled (FC) measurement, which demonstrated superconducting properties. In addition, based on FIG. 25, it is estimated that the critical temperature (Tc) of Compound 4 is about 500K.

### Example 3: Characterization of Superconducting Compound 5

Superconducting Compound 5 was prepared following the procedure described above except that the sintering lasted 24 hours at 750° C. The sample was then slowly cooled to 200° C. The composition of Compound 5 was measured by EDS and the results are summarized in Table 5 below. As shown in Table 5, the atomic fractions suggest that Compound 5 has the following formula: Bi₂SrRb_{1.5}Ca_{0.5}Cu_{1.5}O₁₇F. This formula indicates intergrowth of Rb-2212 phase and Rb-2201 phase as indicated also by XRD and magnetic measurements.

TABLE 5

| Bi at % | Sr at % | Rb at % | Ca at % | Cu at % | O at % | F at % |
|---|---|---|---|---|---|---|
| 8.305 | 3.584 | 6.206 | 2.224 | 6.078 | 70.028 | 3.574 |

The magnetic measurements of Compound 5 were performed and the results are shown in FIG. 26. As shown in FIG. 26, when measured at 1 T magnetic field strength, Compound 5 exhibited hysteresis effects in its magnetic measurements between the Zero Field Cooled (ZFC) measurement (i.e., the lower curve) and the Field Cooled (FC) measurement (i.e., the upper curve), which demonstrated superconducting properties. In addition, based on FIG. 26, it is estimated that the critical temperature (Tc) of Compound 5 is about 500K.

### Example 4: Characterization of Superconducting Compound 6

Superconducting Compound 6 was prepared following the procedure described above except that the sintering cycle was performed three times, the sintering of the first cycle lasted 48 hours at 720° C., the sintering of the second cycle lasted 16 hours at 720° C., and the sintering of the third cycle lasted 19 hours at 720° C. The composition of Compound 6 was measured by EDS and the results are summarized in Table 6 below. As shown in Table 6, the atomic fractions suggest that Compound 6 has the following formula: Bi₂Sr_{0.7}Rb_{0.65}CaCu_{1.5}O₁₁F. Similar to Compound 5, this formula suggests an intergrowth of Rb-2212 phase and Rb-2201 phase.

TABLE 6

| Bi at % | Sr at % | Rb at % | Ca at % | Cu at % | O at % | F at % |
|---|---|---|---|---|---|---|
| 11.120 | 3.921 | 3.573 | 5.120 | 7.510 | 63.230 | 5.526 |

### Example 5: Characterization of Superconducting Compound 7

Superconducting Compound 6 was prepared following the procedure described above except that the sintering cycle was performed three times, the sintering of the first cycle lasted 96 hours at 750° C., the sintering of the second cycle lasted 24 hours at 750° C. and the sintering of the third cycle lasted 72 hours at 750° C. The composition of Compound 7 was measured by EDS and the results are summarized in Table 7 below. As shown in Table 7, the atomic fractions suggest that Compound 7 has the following formula: Bi₂Sr_{0.75}Rb_{0.75}Ca_{1.2}Cu_{1.2}O₇F_{1.7}.

TABLE 7

| Bi at % | Sr at % | Rb at % | Ca at % | Cu at % | O at % | F at % |
|---|---|---|---|---|---|---|
| 13.722 | 5.306 | 5.242 | 8.246 | 8.022 | 47.963 | 11.498 |

Other embodiments are within the scope of the following claims.

1. A compound of formula (I): 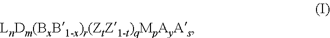
wherein
n is a number from 0 to 3;
m is a number from 0 to 6;
x is a number from 0.1 to 1;
r is a number from 1 to 8;
t is a number from 0 to 1;
q is a number from 0 to 6;
p is a number from to 7;
s is a number from 0 to 20;
y is a number from 0 to 20;
L comprises at least one metal ion selected from the group consisting of transition metal ions and post-transition metal ions;
D comprises at least one element selected from the group consisting of the elements in Groups IIIA and IVA in Periodic Table;
B comprises at least one first alkali metal ion;
B′ comprises at least one first ion selected from the group consisting of alkaline earth metal ions and rare earth metal ions;
Z comprises at least one second alkali metal ion;
Z′ comprises at least one second ion selected from the group consisting of alkaline earth metal ions and rare earth metal ions;
M comprises at least one transition metal ion;
A comprises at least one chalcogen anion; and
A′ comprises at least one halogen anion;
wherein the compound is a crystalline compound.

2. The compound of claim 1, wherein L comprises Bi, Ti, Cu, or Hg, D comprises C, Si, Ge, Sn, Pb, or Al, B comprises Li, Na, K, Rb, or Cs, and B′ comprises La, Mg, Ca, Sr, or Ba, Z comprises Li, Na, K, Rb, or Cs, Z′ comprises Ca or Y, M comprises Cu or Fe, A comprise O, S, or Se, and A′ comprises F, Cl, Br, or I.

3-12. (canceled)

13. The compound of claim 1, wherein the compound satisfies the following equation: x*r+t*q=s.

14. The compound of claim 1, wherein the compound is of formula (Ia): LₙDₘ(BₓB′₁₋ₓ)ᵣ(ZᵣZ′₁₋ₜ)_{q}MₚA_{y}A′ₛA″ᵤ (Ia), in which A″ is a halogen anion and is different from A′, and u is a number from 0 to 20.

15. The compound of claim 14, wherein the compound satisfies the following equation: x*r=s and the compound further satisfies the following equation: t*q=u.

16. (canceled)

17. The compound of claim 1, wherein B′ is a metal ion having a first atomic number, Z′ is a metal ion having a second atomic number, and the second atomic number is smaller than the first atomic number.

18. (canceled)

19. The compound of claim 1, wherein the compound is a superconductor at the temperature of at least 200K.

20. The compound of claim 1, wherein the compound has a tetragonal or orthorhombic crystal structure.

21. A compound, wherein the compound is a crystalline metal oxide comprising at least one transition metal ion, at least one alkaline earth metal ion or at least one rare earth metal ion, and at least one chalcogen anion, in which from 10% to 100% of the at least one alkaline earth metal ion or at least one rare earth metal ion is replaced by an alkali metal ion and from 10% to 100% of the at least one chalcogen anion is replaced by a halogen anion.

22. The compound of claim 21, wherein the crystalline metal oxide before modification is Bi₂Sr₂CaCu₂O_{y}, Bi₂Sr₂Ca₂Cu₃O_{y}, or YBa₂Cu₃O_{y}

23. (canceled)

24. The compound of claim 21, wherein from 50% to 100% of the at least one alkaline earth metal ion or at least one rare earth metal ion is replaced by the alkali metal ion.

25. (canceled)

26. The compound of claim 21, wherein at least one apical chalcogen anion is replaced by the halogen anion.

27. (canceled)

28. A method, comprising:
mixing at least one metal oxide with at least first and second salts, wherein the at least one metal oxide comprises at least one transition or post-transition metal cation, the first salt is an alkali metal halogen salt containing an alkali metal cation and a halogen anion to form a mixture, the second salt comprises an alkaline earth or rare earth metal cation, and the atomic ratio between the alkali metal cation and the alkaline earth or rare earth n metal cation is at least 1:1; and
sintering the mixture at an elevated temperature to form a crystalline compound containing the alkali metal cation and the halogen anion.

29. The method of claim 28, wherein the metal oxide is CuO, Y₂O₃, or Bi203 and the second salt comprises an alkaline earth metal cation and at least one carbonate anion.

30-31. (canceled)

32. The method of claim 28, wherein sintering the mixture comprises sintering the mixture in an inert atmosphere.

33. The method of claim 28, wherein the crystalline compound comprises a modified yttrium barium copper oxide (YBCO) material, and
wherein the elevated temperature is between 700° C. and 850° C.

34. The method of claim 28, wherein the crystalline compound comprises a modified bismuth strontium calcium copper oxide (BSCCO) material, and
wherein the elevated temperature is between 690° C. and 820° C.

35-37. (canceled)

38. The method of claim 28, comprising:
grinding the crystalline compound; and
re-sintering the ground crystalline compound.

39. The method of claim 28, comprising:
melting and recrystallizing the crystalline compound using a micro pulling down (μ-PD) process in an inert atmosphere, to obtain a crystalline fiber.

40. The method of claim 39, wherein the crystalline fiber comprises at least 90% by volume a Bi2212 compound, a Bi2201 compound, or both the Bi2212 compound and the Bi2201 compound.

41. (canceled)

42. The method of claim 39, comprising providing a temperature gradient in a growth direction during the μ-PD process of between 10° C./mm and 100° C./mm and providing a temperature gradient in an axial direction during the μ-PD process of between 100° C./mm and 300° C./mm.

43-62. (canceled)

63. A method, comprising forming a crystal comprising the compound of claim 1, wherein one or more layers of the crystal are formed using pulsed laser deposition.
